(19) United States
(12) Patent Application Publication
(10) Pub. No.: US 2011/0186425 A1
(43) Pub. Date: Aug. 4, 2011

(54) MAGNETRON SPUTTERING METHOD, AND MAGNETRON SPUTTERING APPARATUS

(75) Inventors: Tadahiro Ohmi, Miyagi (JP); Tetsuya Goto, Miyagi (JP); Nobuaki Seki, Miyagi (JP); Satoru Kawakami, Miyagi (JP); Takaaki Matsuoka, Tokyo (JP)

(73) Assignees: TOKYO ELECTRON LIMITED, Tokyo (JP); TOHOKU UNIVERSITY, Sendai-Shi (JP)

(21) Appl. No.: 12/999,985

(22) PCT Filed: Jun. 17, 2009
(86) PCT No.: PCT/JP2009/060992

§ 371 Date: Jan. 19, 2011

(30) Foreign Application Priority Data
Jun. 19, 2008 (JP) 2008-160991

(51) Int. Cl. C23C 14/35

(52) U.S. Cl. 204/298.08; 204/298.12

(57) ABSTRACT

A sputtering method includes disposing a plurality of thin and long deposition regions such that the thin and long deposition regions each cross in a first direction a circular reference region having a diameter equal to that of a semiconductor wafer, and are arranged at predetermined intervals in a second direction perpendicular to the first direction; disposing one of the plurality of thin and long deposition regions such that one side of sides thereof extending in the first direction passes through a substantial center of the circular reference region; disposing another of the plurality of thin and long deposition regions such that one side of sides thereof extending in the first direction passes through a substantial edge of the circular reference region; setting each of widths of the plurality of thin and long deposition regions such that a value obtained by summing the widths of the plurality of thin and long deposition regions in the second direction is substantially equal to a radius of the circular reference region; disposing a plurality of thin and long targets to face the corresponding thin and long deposition regions such that sputtering particles emitted from the plurality of thin and long targets are incident on the corresponding thin and long deposition regions; disposing a semiconductor wafer, while overlapping with the circular reference region; confining a plasma generated by a magnetron discharge in the vicinity of the targets, and emitting the sputtering particles from the targets; and rotating the semiconductor wafer at a predetermined rotation speed by using a normal line passing through the center of the circular reference region as a rotation central axis, to deposit a film on a surface of the semiconductor wafer.

The present international application claims the benefit of Japanese Patent Application No. 2008-160991, filed on Jun. 19, 2008, in Japan Patent Office, and the disclosure of which is incorporated herein in its entirety by reference.

### TECHNICAL FIELD

The present invention relates to a magnetron sputtering method that uses a magnetron discharge during a sputtering process, and more particularly, to a magnetron sputtering method and a magnetron sputtering apparatus that use a semiconductor wafer as an object to be processed.

### BACKGROUND ART

In the manufacture of a semiconductor device, a process of forming a predetermined thin film on a semiconductor wafer and a process of patterning by lithography and etching the thin film are repeated several times. Sputtering methods, which are physical vapor deposition (PVD) methods where a target (a basic material for the thin film) is sputtered by ion bombardment and atoms of the target material are deposited onto a semiconductor wafer, are widely used in a semiconductor process. From among sputtering methods, a magnetron sputtering method is the most practical and most generally used.

In a magnetron sputtering method, a magnet is disposed on a rear side of a cathode-side target, generally in a parallel planar diode sputtering device and a magnetic field leaking to a front side of the target is formed. Here, the magnet having N-S poles is disposed in such a manner that the leakage magnetic field has a component parallel to a target surface, and the parallel magnetic component is parallel to the target surface and is distributed in a loop shape in a direction perpendicular to a line of magnetic force. As such, secondary electrons ejected from the target surface due to ion incidence move in a closed cycloidal manner along the loop due to a Lorentz force to be captured in the vicinity of the target surface, thereby promoting plasmatization or ionization of a sputtering gas due to a magnetron discharge. By using the magnetron sputtering method, since high current density is achieved even at a low pressure, sputter film formation at low temperature and high speed can be performed.

In the magnetron sputtering method for typical parallel planar diode sputtering, a circular plate-shaped or polygonal plate-shaped target is used. In this case, if the leakage magnetic field formed on the target surface is stopped, only a region of the target surface facing the loop, that is, a plasma ring, is locally eroded, and thus target utilization efficiency is low and uniformity of sputter film formation is not good. Accordingly, a mechanism for appropriately moving (rotating/linearly moving/shaking) the magnet at the rear side of the target in order to make an area of the target surface affected by the plasma ring as large as possible is provided.

In Patent Document 1, there is disclosed a magnetron sputtering apparatus that, by using a relatively thin and long polygonal plate-shaped target, that is, a thin and long target, moves an eroded region of a target surface in a lengthwise direction of the target, to improve target utilization efficiency and uniformity of sputter film formation. In the magnetron sputtering apparatus, a rotating magnet group is provided at a rear side of the target by respectively attaching plate magnets having N poles and plate magnets having S poles in spiral shapes at predetermined intervals in an axial direction in an outer circumference of a columnar rotary shaft that extends in a direction parallel to the lengthwise direction of the target. A fixed outer circumferential plate magnet which has a rectangular frame-shape, has contour dimensions (width and length) substantially equal to those of the target, and surrounds the rotating magnet group in the vicinity of a rear surface of the target is provided. A plurality of plasma rings each having a substantially oval shape having a major axis substantially equal to a spiral pitch and a minor axis substantially equal to a width of the target are formed in the axial direction on the target surface. The rotating magnet group is rotated with the columnar rotary shaft, to move the plurality of plasma rings in the lengthwise direction of the target.

[Patent Document 1] WO2007/043476

### DISCLOSURE OF THE INVENTION

### Technical Problem

However, when the rotating magnet group attached to the columnar rotary shaft is magnetically coupled to the fixed outer circumferential plate magnet disposed around the rotating magnet group, theoretically, it is known that a size of the thin and long target has no limitation in the axial direction but has a limitation of 120 to 130 mm in a widthwise direction. Accordingly, it is impossible to uniformly performing sputter film formation on a circular object to be processed having a relatively large diameter, for example, a semiconductor wafer having a diameter of 300 mm, by using one thin and long target. Also, since the target is supported on a backing plate that is larger than the target and an insulating member or a power feeding system is connected around the backing plate, it is impossible to collectively arrange a plurality of thin and long targets in the widthwise direction, that is, to increase the width of the target.

For these reasons, it has been thought that it is very difficult to use or actually apply the aforesaid thin and long target in a magnetron sputtering method using a semiconductor wafer as an object to be processed.

Considering the aforesaid shortcomings and problems of the prior art, the present invention is provided. According to the present invention, a magnetron sputtering method and a magnetron sputtering apparatus that can efficiently and uniformly perform sputter film formation on a semiconductor wafer by using a thin and long target are provided.

### Technical Solution

To achieve the objective, a magnetron sputtering method in a first aspect of the present invention includes: disposing a plurality of thin and long deposition regions such that the the pluality of thin and long deposition regions each cross in a first direction a circular reference region having a diameter equal to that of a semiconductor wafer, and are arranged at predetermined intervals in a second direction perpendicular to the first direction; disposing one of the plurality of thin and long deposition regions such that one side of sides thereof extending in the first direction passes through a substantial center of the circular reference region; disposing another of the plurality of thin and long deposition regions such that one side of sides thereof extending in the first direction passes through a substantial edge of the circular reference region; setting widths of the plurality of thin and long deposition regions such that a value obtained by summing the widths of the plurality of thin and long deposition regions in the second direction is substantially equal to a radius of the circular reference region; disposing a plurality of thin and long targets to face the corresponding thin and long deposition regions such that sputtering particles emitted from the plurality of thin and long targets are incident on the corresponding thin and long deposition regions; disposing a semiconductor wafer as an object to be processed at a position overlapping with the circular reference region; driving a moving magnet at a rear side of each of the plurality of thin and long targets to confine a plasma, which is generated by a magnetron discharge, in the vicinity of each of the targets, and emitting the sputtering particles from surfaces of the targets; and rotating the semiconductor wafer at a predetermined rotation speed coaxially by using a normal line passing through the center of the circular reference region as a rotation central axis, to form a deposition film of the sputtering particles on a surface of the semiconductor wafer.

A magnetron sputtering apparatus in the first aspect of the present invention includes: a processing container which is depressurizable to evacuate gas; a rotatable stage which supports a semiconductor wafer in the processing container; a rotation driving unit which rotates the stage at a desired rotation speed; a plurality of targets which are arranged to face the stage such that the plurality of targets each have a length equal to or greater than a predetermined value in a first direction and are arranged at predetermined intervals in a second direction perpendicular to the first direction; a gas supply mechanism which supplies a sputtering gas into the processing container; a power supply mechanism which discharges the sputtering gas in the processing container; and a magnetic field generation mechanism which comprises a magnet provided at a rear side of each of the plurality of targets in order to confine a plasma, which is generated in the processing container, in the vicinity of each of the plurality of targets, wherein a plurality of thin and long deposition regions are arranged such that the plurality of thin and long deposition regions each cross in the first direction a circular reference region having a diameter equal to that of the semiconductor wafer, and are arranged at predetermined intervals in the second direction, wherein one of the plurality of thin and long deposition regions is disposed such that one side of sides thereof extending in the first direction passes through a substantial center of the circular reference region, wherein another of the plurality of thin and long deposition regions is disposed such that one side of sides thereof extending in the first direction passes through a substantial edge of the circular reference region, wherein a value obtained by summing widths of the plurality of thin and long deposition regions in the second direction is substantially equal to a radius of the circular reference region, wherein the semiconductor wafer is disposed at a position overlapping with the circular reference region, wherein the stage and the semiconductor wafer are coaxially rotated by the rotation driving unit and sputtering particles emitted from surfaces of the plurality of targets are incident on the corresponding thin and long deposition regions, to form a deposition film of the sputtering particles on a surface of the semiconductor wafer.

According to the magnetron sputtering method or the magnetron sputtering apparatus in the first aspect of the present invention, since one or more thin and long deposition regions are passed while a semiconductor wafer is rotated one time and each portion corresponding to 180° on a surface of the semiconductor wafer is uniformly exposed to sputtering particles, a thin film may be formed at a film formation rate with high uniformity on the semiconductor wafer.

A magnetron sputtering method in a second aspect of the present invention includes: disposing a plurality of thin and long deposition regions such that the thin and long deposition regions each cross in a first direction a circular reference region having a diameter equal to that of a semiconductor wafer, and are arranged at predetermined intervals in a second direction perpendicular to the first direction; disposing one of the plurality of thin and long deposition regions such that one side of sides thereof extending in the first direction passes through a substantial center of the circular reference region; disposing another of the plurality of thin and long deposition regions such that one side of sides thereof extending in the first direction passes through a substantial edge of the circular reference region; setting widths of the plurality of thin and long deposition regions such that a value obtained by summing the widths of the plurality of thin and long deposition regions in the second direction is substantially equal to a radius of the circular reference region; disposing a plurality of thin and long targets to face the corresponding thin and long deposition regions such that sputtering particles emitted from the plurality of thin and long targets are incident on the corresponding thin and long deposition regions; disposing a semiconductor wafer as an object to be processed at a predetermined position spaced apart from the circular reference region by a predetermined distance within a surface including the circular reference region; driving a moving magnet at a rear side of each of the plurality of thin and long targets to confine a plasma, which is generated by a magnetron discharge, in the vicinity of each of the targets, and emitting the sputtering particles from surfaces of the targets; and rotating the semiconductor wafer at a predetermined rotation speed eccentrically by using a normal line passing through the center of the circular reference region as a rotation central axis, to form a deposition film of the sputtering particles on a surface of the semiconductor wafer.

A magnetron sputtering apparatus in the second aspect of the present invention includes: a processing container which is depressurizable to evacuate gas; a rotatable stage which supports a semiconductor wafer in the processing container; a rotation driving unit which rotates the stage at a desired rotation speed; a plurality of targets which are arranged to face the stage such that the plurality of targets each have a length equal to or greater than a predetermined value in a first direction and are arranged at predetermined intervals in a second direction perpendicular to the first direction; a gas supply unit which supplies a sputtering gas into the processing container; a power supply unit which discharges the sputtering gas in the processing container; and a magnetic field generation mechanism which comprises a magnet provided at a rear side of each of the plurality of targets in order to confine a plasma, which is generated in the processing container, in the vicinity of each of the targets, wherein a plurality of thin and long deposition regions are arranged such that the plurality of thin and long deposition regions each cross in the first direction a circular reference region having a diameter equal to that of the semiconductor wafer and are arranged at predetermined intervals in the second direction, wherein one of the plurality of thin and long deposition regions is disposed such that one side of sides thereof extending in the first direction passes through a substantial center of the circular reference region, wherein another of the plurality of thin and long deposition regions is disposed such that one side of sides thereof extending in the first direction passes through a substantial edge of the circular reference region, wherein a value obtained by summing widths of the plurality of thin and long deposition regions in the second direction is substantially equal to a radius of the circular reference region, wherein the semiconductor wafer is disposed at a position where a center of the semiconductor wafer is spaced apart from the center of the circular reference region by a predetermined distance within a surface including the circular reference region, wherein the semiconductor wafer is eccentrically rotated by rotating the stage by using the rotation driving unit and sputtering particles emitted from surfaces of the plurality of targets are incident on the corresponding thin and long deposition regions, to form a deposition film of the sputtering particles on a surface of the semiconductor wafer.

According to the method or the device in the second aspect of the present invention, since not only the effect of the first aspect can be achieved but also an abnormal singularity of a film formation rate is surely prevented, thus the uniformity of a film formation rate can be further improved.

In the method or the device in the first and second aspects, according to a preferable embodiment, when a radius of the semiconductor wafer is R and a number of the thin and long deposition regions is N (N is an integer equal to or greater than 2), a width of each of the plurality of thin and long deposition regions in the second direction may be R/N.

A magnetron sputtering method in a third aspect of the present invention includes: disposing a plurality of thin and long deposition regions such that the plurality of thin and long deposition regions each cross in a first direction a circular reference region having a diameter equal to that of a semiconductor wafer and are arranged at predetermined intervals in a second direction perpendicular to the first direction; disposing one of the plurality of thin and long deposition regions such that a center of the circular reference region is located in an inside of the one of the thin and long deposition regions, and one side of sides thereof extending in the first direction passes through a position spaced apart from the center of the circular reference region by a first distance; disposing another of the plurality of thin and long deposition regions such that one side of sides thereof extending in the first direction passes through a position spaced outward by a second distance from edges of the circular reference region; setting each of widths of the plurality of thin and long deposition regions such that a value obtained by summing the widths of the plurality of thin and long deposition regions in the second direction is greater by a predetermined excess size than a radius of the circular reference region; disposing a plurality of thin and long targets to face the corresponding thin and long deposition regions such that sputtering particles emitted from the plurality of thin and long targets are incident on the corresponding thin and long deposition regions; disposing a semiconductor wafer as an object to be processed at a position where a center thereof is spaced apart from the center of the circular reference region by a third distance within a surface including the circular reference region; driving a moving magnet at a rear side of each of the plurality of thin and long targets to confine a plasma, which is generated by a magnetron discharge, in the vicinity of the targets, and emitting the sputtering particles from surfaces of the targets; and eccentrically rotating the semiconductor wafer at a predetermined rotation speed by using a normal line passing through the center of the circular reference region as a rotation central axis, to form a deposition film of the sputtering particles on a surface of the semiconductor wafer.

Also, a magnetron sputtering apparatus in the third aspect of the present invention includes: a processing container which is depressurizable to evacuate gas; a rotatable stage which supports a semiconductor wafer in the processing container; a rotation driving unit which rotates the stage at a desired rotation speed; a plurality of targets which are arranged to face the stage such that the plurality of targets each have a length equal to or greater than a predetermined value in a first direction and are arranged at predetermined intervals in a second direction perpendicular to the first direction; a gas supply mechanism which supplies a sputtering gas into the processing container; a power supply mechanism for discharging the sputtering gas in the processing container; and a magnetic field generation mechanism which comprises a magnet provided at a rear side of each of the targets in order to confine a plasma, which is generated in the processing container, in the vicinity of each of the plurality of targets, wherein a plurality of thin and long deposition regions are arranged such that the plurality of thin and long deposition regions each cross a circular reference region in the first direction, and are arranged at predetermined intervals in the second direction,

wherein, in the second direction, one of the plurality of thin and long deposition regions is disposed such that a center of the circular reference region is located in an inside of the one of the plurality of thin and long deposition regions and one side of sides thereof extending in the first direction passes through a position spaced apart from the center of the circular reference region by a first distance, wherein another of the plurality of thin and long deposition regions is disposed such that one side of sides thereof extending in the first direction passes through a position spaced apart from an edge of the circular reference region by a second distance, wherein, in the second direction, a value obtained by summing widths of the plurality of thin and long deposition regions is greater by a predetermined excess size than the radius of the circular reference region, and the semiconductor wafer is disposed at a position where a center of the semiconductor wafer is spaced apart from the center of the circular reference region by a third distance within a surface including the circular reference region, wherein the semiconductor wafer is eccentrically rotated together with the stage by using the rotation driving unit and sputtering particles emitted from surfaces of the targets are incident on the corresponding thin and long deposition regions, to form a deposition film of the sputtering particles on a surface of the semiconductor wafer.

According to the method or the device in the third aspect of the present invention, since not only the effects of the first and second aspects can be achieved but also film formation rate characteristics on a wafer central portion and a wafer circumferential portion are improved, thus the uniformity of an in-plane film formation rate can be further improved.

In a very appropriate embodiment of the present invention, the excess size may be equal to a value obtained by summing the first distance and the second distance. Also, the third distance may be equal to the second distance.

Also, in a very appropriate embodiment, a diameter of the semiconductor wafer may be determined to be 300 mm, a number of the targets may be determined to be 2, and the second distance may be determined to be about 15 mm. Alternatively, a diameter of the semiconductor wafer may be determined to be 300 mm, a number of the targets may be determined to be 3, and the second distance may be determined to be about 10 mm.

In a very appropriate embodiment, the plurality of thin and long deposition regions may have one pair of long sides parallel to the first direction. Also, the plurality of thin and long deposition regions may have one pair of long sides thereof extending in the first direction, and a recess portion or a convex portion may be formed on at least one of the pair of long sides. Also, very appropriately, lengths, in the first direction, of the thin and long deposition regions may be longer as the thin and long deposition region is closer to a center of the circular reference region and shorter as the thin and long deposition region is farther from an edge of the circular reference region

In a very appropriate embodiment, the magnetic field generation mechanism may form a circular or oval plasma ring that extends from one end to another end of the surfaces of the targets in the second direction, and move the plasma ring in the first direction.

In a very appropriate embodiment, the magnetic field generation mechanism may receive the magnets disposed at the rear side of the plurality of targets in a common housing. The housing may be formed of a magnetic substance in a very appropriate embodiment.

In a very appropriate embodiment, the housing may be airtightly attached to the processing container to depressurize the housing.

Also, in a very appropriate embodiment, the magnetic sputtering device may include a mechanism for varying a distance between the targets and the magnetic field generation mechanism according to a degree of erosion on the surfaces of the targets in order to constantly maintain a strength of a magnetic field on the surfaces of the targets.

In a very appropriate embodiment, the magnetic sputtering device may include a slit which is disposed between at least one of the plurality of targets and the stage and defines each of the thin and long deposition regions.

In a very appropriate embodiment, the magnetron sputtering apparatus may include a collimator which is disposed between each of the targets and the stage and controls the sputtering particles emitted from each target to be perpendicularly incident on the corresponding thin and long deposition region.

In a very appropriate embodiment, the magnetron sputtering apparatus may include an ionization plasma generation portion which generates a plasma for ionizing the sputtering particles between each of the targets and the stage.

In a very appropriate embodiment, the magnetron sputtering apparatus may include one common backing plate which holds the plurality of targets arranged on one continuous surface.

In a very appropriate embodiment, the power supply mechanism may include a direct current power source electrically connected commonly to the plurality of targets with the backing plate therebetween.

The power supply mechanism may include a high frequency power source electrically connected commonly to the plurality of targets with the backing plate therebetween.

In a very appropriate embodiment, a plurality of the stages may be arranged in the first direction in one processing container, each of the targets may be arranged to face the corresponding thin and long deposition regions while ranging over the plurality of semiconductor wafers in the first direction, and sputter film formation is performed simultaneously on the semiconductor wafers by simultaneously rotating the plurality of semiconductor wafers on the plurality of stages.

A sputtering device in another aspect of the present invention includes: a processing container which is depressurizable to evacuate gas; a stage which is provided in the processing container, allows a semiconductor wafer to be disposed thereon, and is rotatable about a rotary shaft; and a sputtering mechanism which is disposed to face the stage, is able to support a target extending in a first direction, and is able to emit sputtering particles from a surface of the target to a thin and long deposition region extending in the first direction, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to the one of the plurality of sputtering mechanisms passes through a substantial center of the rotary shaft, wherein another of the plurality of sputtering mechanisms is disposed such that one side of sides extending in the first direction in the thin and long deposition region corresponding to the another of the plurality of sputtering mechanisms passes through a substantial edge of a semiconductor wafer arrangement region of the stage and the other side thereof passes through the semiconductor wafer arrangement region of the stage, wherein a value obtained by summing widths, in the second direction, of the thin and long deposition regions corresponding to the plurality of sputtering mechanisms is substantially equal to a radius of the semiconductor wafer arrangement region.

A sputtering device in another aspect of the present invention includes: a processing container which is depressurizable to evacuate gas; a stage which is provided in the processing container, allows a semiconductor wafer to be disposed thereon, and is rotatable about a rotary shaft; and a sputtering mechanism which is disposed to face the stage, is able to support a target extending in a first direction, and is able to emit sputtering particles from a surface of the target to a thin and long deposition region extending in the first direction, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to the one of the plurality of sputtering mechanisms passes through a substantial center of the rotary shaft, wherein another of the plurality of sputtering mechanisms is disposed such that one side of sides extending in the first direction in the thin and long deposition region corresponding to the another of the plurality of sputtering mechanisms passes through a substantial edge of a semiconductor wafer arrangement region of the stage or a position spaced apart from the edge of the semiconductor wafer arrangement region by a predetermined distance, and the other side passes through an inside of the semiconductor wafer arrangement region of the stage, wherein a mechanism for holding the semiconductor wafer is provided such that a center of the semiconductor wafer arrangement region is spaced apart from the center of the rotary shaft by the same distance as the predetermined distance.

In the above configuration, preferably, three or more sputtering mechanism may be disposed at predetermined intervals in the second direction perpendicular to the first direction, wherein yet another of the plurality of sputtering mechanisms is disposed such that the thin and long deposition region corresponding to the yet another of the plurality of sputtering mechanisms is located at a position opposite to the thin and long deposition region corresponding to the another of the plurality of sputtering mechanisms with respect to the thin and long deposition region corresponding to the one of the plurality of sputtering mechanisms, and passes through an inside of the semiconductor wafer arrangement region.

Also, a width of the thin and long deposition region corresponding to the yet another of the plurality of sputtering mechanisms may be substantially equal to an interval between the thin and long deposition region corresponding to the one of the plurality of sputtering mechanisms and the thin and long deposition region of the another of the plurality of sputtering mechanisms.

Also, when a radius of the semiconductor wafer arrangement region is R and a number of the thin and long deposition regions is N (N is an integer equal to or greater than 2), a width of each of the plurality of thin and long deposition regions in the second direction may be R/N.

A sputtering device in another aspect of the present invention includes: a processing container which is depressurizable to evacuate gas; a stage which is provided in the processing container, allows a semiconductor wafer to be disposed thereon, and is rotatable about a rotary shaft; and a sputtering mechanism which is disposed to face the stage, is able to support a target extending in a first direction, and is able to emit sputtering particles from a surface of the target to a thin and long deposition region extending in the first direction, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to one of the plurality of sputtering mechanisms passes through a position spaced apart from a center of the rotary shaft by a first distance and another side passes through a semiconductor wafer arrangement region of the stage, wherein another of the plurality of sputtering mechanisms is disposed such that one side of sides extending in the first direction in the thin and long deposition region corresponding to another of the plurality of sputtering mechanisms passes through a position spaced apart from an edge of the semiconductor wafer arrangement region of the stage by a second distance and another side passes through the semiconductor wafer arrangement region, wherein a value obtained by summing widths, in the second direction, of the thin and long deposition regions corresponding to the plurality of sputtering mechanisms is greater by at least the second distance than a radius of the semiconductor wafer arrangement region.

A sputtering device in another aspect of the present invention includes: a processing container which is depressurizable to evacuate gas; a stage which is provided in the processing container, allows a semiconductor wafer to be disposed thereon, and is rotatable about a rotary shaft; and a sputtering mechanism which is disposed to face the stage, is able to support a target extending in a first direction, and is able to emit sputtering particles from a surface of the target to a thin and long deposition region extending in the first direction, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to one of the plurality of sputtering mechanisms passes through a position spaced apart from a center of the rotary shaft by a first distance and another side passes through a semiconductor wafer arrangement region of the stage, wherein another of the plurality of sputtering mechanisms is disposed such that one side of sides extending in the first direction in the thin and long deposition region corresponding to the another of the plurality of sputtering mechanisms passes through a position spaced apart from an edge of the semiconductor wafer arrangement region of the stage by a second distance or a position spaced apart by at most a third distance from the position spaced apart by the second distance and another side passes through the semiconductor wafer arrangement region, wherein a mechanism for holding the semiconductor wafer is provided such that a center of the semiconductor wafer arrangement region is spaced apart from the center of the rotary shaft by the same distance as the third distance.

In a preferable embodiment, three or more sputtering mechanisms may be arranged at predetermined intervals in the second direction perpendicular to the first direction, wherein yet another of the plurality of sputtering mechanisms is disposed such that the thin and long deposition region corresponding to the yet another of the plurality of sputtering mechanisms is located at a position opposite to the thin and long deposition region corresponding to the another of the plurality of sputtering mechanisms with respect to the thin and long deposition region corresponding to the one of the plurality of sputtering mechanisms, and passes through an inside of the semiconductor wafer arrangement region.

Also, in a preferable embodiment, a width of the thin and long deposition region corresponding to the yet another of the plurality of sputtering mechanisms may be substantially equal to an interval between the thin and long deposition region corresponding to the one of the plurality of sputtering mechanisms and the thin and long deposition region corresponding to the another of the plurality of sputtering mechanisms.

Also, in a preferable embodiment, one or both sides of at least one of the thin and long deposition regions may include at least one portion that have a recess shape or a convex shape.

Also, in a preferable embodiment, a diameter of the semiconductor wafer arrangement region may be equal to or greater than 300 mm.

A sputtering method in another aspect of the present invention includes: holding a semiconductor wafer on a semiconductor wafer arrangement region of a stage that is provided in a processing container depressurizable to evacuate gas, and is rotatable about a rotary shaft; rotating the semiconductor wafer by rotating the stage; and by using a sputtering mechanism that is disposed to face the stage, holds a target extending in a first direction, and is able to emit sputtering particles from a surface of the target to a thin and long deposition region extending in the first direction, emitting the sputtering particles from the surface of the target to the thin and long deposition region, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to the one of the plurality of sputtering mechanisms passes through a substantial center of the rotary shaft, wherein another of the plurality of sputtering mechanisms is disposed such that one side of sides extending in the first direction in the thin and long deposition region corresponding to the another of the plurality of sputtering mechanisms passes through a substantial edge of a semiconductor wafer arrangement region of the stage and another side passes through the semiconductor wafer arrangement region of the stage, wherein a value obtained by summing widths, in the second direction, of the thin and long deposition regions corresponding to the plurality of sputtering mechanisms is substantially equal to a radius of the semiconductor wafer arrangement region, wherein the semiconductor wafer passes through the plurality of thin and long deposition regions due to a rotation of the semiconductor wafer to deposit the sputtering particles on a surface of the semiconductor wafer.

A sputtering method in another aspect of the present invention includes: holding a semiconductor wafer on a semiconductor wafer arrangement region of a stage that is provided in a processing container depressurizable to evacuate gas, and is rotatable about a rotary shaft; rotating the semiconductor wafer by rotating the stage; and by using a sputtering mechanism that is disposed to face the stage and holds a target extending in a first direction to emit sputtering particles from a surface of the target to a thin and long deposition region extending in the first direction, emitting the sputtering particles from the surface of the target to the thin and long deposition region, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to the one of the plurality of sputtering mechanisms passes through a substantial center of the rotary shaft, wherein another of the plurality of sputtering mechanisms is disposed such that one side of sides extending in the first direction in the thin and long deposition region corresponding to the another of the plurality of sputtering mechanisms passes through a substantial edge of a semiconductor wafer arrangement region of the stage or a position spaced apart from the edge of the semiconductor wafer arrangement region by a predetermined distance and another side passes through an inside of the semiconductor wafer arrangement region of the stage, wherein the semiconductor wafer is held on the stage such that a center of the semiconductor wafer arrangement region is spaced apart from the center of the rotary shaft by the same distance as the predetermined distance, wherein the semiconductor wafer passes through the plurality of thin and long deposition regions due to an eccentric rotation of the semiconductor wafer to deposit the sputtering particles on a surface of the semiconductor wafer.

In a very appropriate embodiment of the present invention, three or more sputtering mechanisms may be arranged at predetermined intervals in the second direction perpendicular to the first direction, wherein yet another of the plurality of sputtering mechanisms is disposed such that the thin and long deposition region corresponding to the yet another of the plurality of sputtering mechanisms is disposed at a side opposite to the thin and long deposition region corresponding to the another of the plurality of sputtering mechanisms with respect to the thin and long deposition region corresponding to the one of the plurality of sputtering mechanisms, and passes through an inside of the semiconductor wafer arrangement region.

Also, a sputtering method in another aspect of the present invention includes: holding a semiconductor wafer on a semiconductor wafer arrangement region of a stage that is provided in a processing container depressurizable to evacuate gas, and is rotatable about a rotary shaft; rotating the semiconductor wafer by rotating the stage; and by using a sputtering mechanism that is disposed to face the stage, holds a target extending in a first direction, and is able to emit sputtering particles from a surface of the target to a thin and long deposition region extending in the first direction, emitting the sputtering particles from the surface of the target to the thin and long deposition region, wherein a plurality of the sputtering mechanisms are arranged at predetermined intervals in a second direction perpendicular to the first direction, wherein one of a plurality of sputtering mechanisms is disposed such that one side of sides extending in the first direction in the thin and long deposition region corresponding to the one of a plurality of sputtering mechanisms passes through a position spaced apart from a center of the rotary shaft by a first distance and another side passes through the semiconductor wafer arrangement region of the stage, wherein another of the plurality of sputtering mechanisms is disposed such that one side of sides extending in the first direction in the thin and long deposition region corresponding to the another of the plurality of sputtering mechanisms passes through a position spaced apart from edges of the semiconductor wafer arrangement region of the stage by a second distance and another side passes through the semiconductor wafer arrangement region, wherein a value obtained by summing widths, in a second direction, of the thin and long deposition regions corresponding to the plurality of sputtering mechanisms is greater by at least the second distance than a radius of the semiconductor wafer arrangement region, wherein the semiconductor wafer passes through the plurality of thin and long deposition regions due to a rotation of the semiconductor wafer to deposit the sputtering particles on a surface of the semiconductor wafer.

Also, a sputtering method in another aspect of the present invention includes: holding a semiconductor wafer on a semiconductor wafer arrangement region of a stage that is provided in a processing container depressurizable to evacuate gas, and is rotatable about a rotary shaft; rotating the semiconductor wafer by rotating the stage; and by using a sputtering mechanism that is disposed to face the stage, holds a target extending in a first direction, and is able to emit sputtering particles from a surface of the target to a thin and long deposition region extending in the first direction, emitting the sputtering particles from the surface of the target to the thin and long deposition region, wherein a plurality of the sputtering mechanisms are arranged at predetermined intervals in a second direction perpendicular to the first direction, wherein one of the plurality of sputtering mechanisms is disposed such that one side of sides extending in the first direction in the thin and long deposition region corresponding to the one of the plurality of sputtering mechanisms passes through a position spaced apart from a center of the rotary shaft by a first distance and another side passes through the semiconductor wafer arrangement region of the stage, wherein another of the plurality of sputtering mechanisms is disposed such that one side of sides extending in the first direction in the thin and long deposition region corresponding to the another of the plurality of sputtering mechanisms passes through a position spaced apart from an edge of the semiconductor wafer arrangement region of the stage by a second distance or a position spaced apart by at most a third distance from the postion spaced apart by the second distance and another side passes through the semiconductor wafer arrangement region, wherein the semiconductor wafer is held on the stage such that a center of the semiconductor wafer arrangement region is spaced apart from the center of the rotary shaft by the same distance as the third distance, and the semiconductor wafer passes through the plurality of thin and long deposition regions due to an eccentric rotation of the semiconductor wafer to deposit the sputtering particles on a surface of the semiconductor wafer.

### Advantageous Effects

According to the magnetron sputtering method and the magnetron sputtering apparatus of the present invention, due to the above structure and operation, sputter film formation can be efficiently and uniformly performed on a semiconductor wafer by using a thin and long target.

### BRIEF DESCRIPTION OF THE DRAWINGS

FIG. 1 is a perspective view showing a configuration of an example of a thin and long target used in an embodiment of the present invention.

FIG. 2 is a perspective view for explaining a principle of a magnetron sputtering method according to an embodiment of the present invention.

FIG. 3 is a plan view showing a positional relationship between each of portions on a wafer arrangement surface and a wafer W in Embodiment 1 of the present invention.

FIG. 4 is a plan view showing a layout equal to a layout of FIG. 3 in terms of sputter film formation.

FIG. 5 is a diagram showing desirable film formation rate distribution characteristics on the wafer in Embodiment 1 of the present invention.

FIG. 6 is a plan view showing an example of a deviation in a positional relationship that may occur in Embodiment 1.

FIG. 7 is a graph schematically showing a film formation rate distribution in FIG. 6.

FIG. 8 is a plan view showing another example of a deviation in a positional relationship that may occur in Embodiment 1.

FIG. 9 is a graph schematically showing a film formation rate distribution in FIG. 8.

FIG. 10 is a plan view showing a positional relationship of each of portions and a position of a wafer when the wafer rotates in Embodiment 2.

FIG. 11 is a plan view showing a positional relationship of each of the portions and a position of the wafer when the wafer rotates in Embodiment 2.

FIG. 12 is a plan view showing a positional relationship of each of the portions and a position of the wafer when the wafer rotates in Embodiment 2.

FIG. 13 is a plan view showing a positional relationship of each of the portions and a position of the wafer when the wafer rotates in Embodiment 2.

FIG. 14 is a diagram showing condition settings used in a simulation in Embodiment 2.

FIG. 15 is a diagram showing a standardized film formation rate distribution obtained in the simulation in Embodiment 2.

FIG. 16 is a plan view showing an example of a positional relationship of each of portions and an arrangement position of a wafer in Embodiment 3.

FIG. 17 is a diagram showing condition settings used in a simulation in Embodiment 3.

FIG. 18 is a graph showing a standardized film formation rate distribution obtained in the simulation in Embodiment 3.

FIG. 19A is a graph showing in-plane uniformity when a film formation rate ratio between a center and edges on a thin and long deposition region and an eccentric amount of a wafer eccentric rotation are parameters in Embodiment 2.

FIG. 19B is another graph showing in-plane uniformity when a film formation rate ratio between a center and edges on a thin and long deposition region and an eccentric amount of a wafer eccentric rotation are parameters in Embodiment 3.

FIG. 20 is a plan view showing an example of a positional relationship of each of portions and an arrangement position of a wafer in the case of a 2-target method of Embodiment 4.

FIG. 21A is a diagram showing standardized film formation rate distribution characteristics in the case of a 2-target method of Embodiment 4.

FIG. 21 B is another diagram showing standardized film formation rate distribution characteristics in the case of a 2-target method of Embodiment 4.

FIG. 22 is a plan view showing an example of a positional relationship of each of portions and an arrangement position of a wafer in the case of a 3-target method of Embodiment 4.

FIG. 23A is a diagram showing standardized film formation rate distribution characteristics in the case of a 3-target method of Embodiment 4.

FIG. 23B is another diagram showing standardized film formation rate distribution characteristics in the case of a 3-target method of Embodiment 4.

FIG. 24 is a schematic cross-sectional view showing a configuration of a magnetron sputtering apparatus according to an embodiment of the present invention.

FIG. 25 is a perspective view of a columnar rotary shaft, a group of a plurality of magnets, a plate magnet, and a paramagnetic body in the magnetron sputtering apparatus, and a view thereof seen from a target side.

FIG. 26A is a perspective view showing a region where a plasma ring is generated in the magnetron sputtering apparatus of an embodiment.

FIG. 26B is another perspective view showing the region where a plasma ring is generated in the magnetron sputtering apparatus of an embodiment.

FIG. 27 is a diagram showing an example of a profile where a problem occurs in film formation distribution rate characteristics on a wafer.

FIG. 28 is a plan view showing a modified example of a slit or a thin and long deposition region for improving the film formation distribution rate characteristics of FIG. 27.

FIG. 29A is a view showing an example of a configuration in which a collimator is provided in the magnetron sputtering apparatus of an embodiment.

FIG. 29B is another view showing an example of a configuration in which the collimator is provided in the magnetron sputtering apparatus of an embodiment.

FIG. 30 is a view showing an example of a structure in which an ionization plasma generation portion is provided in the magnetron sputtering apparatus.

FIG. 31A is a view showing an example of a configuration in which a plurality of rotation stages 22 are provided in one chamber 20 in the magnetron sputtering apparatus.

FIG. 31B is another view showing an example of a configuration in which the plurality of rotation stages 22 are provided in one chamber 20 in the magnetron sputtering apparatus.

### BEST MODE FOR CARRYING OUT THE INVENTION

Hereinafter, very appropriate embodiments of the present invention will be explained with reference to the attached drawings.

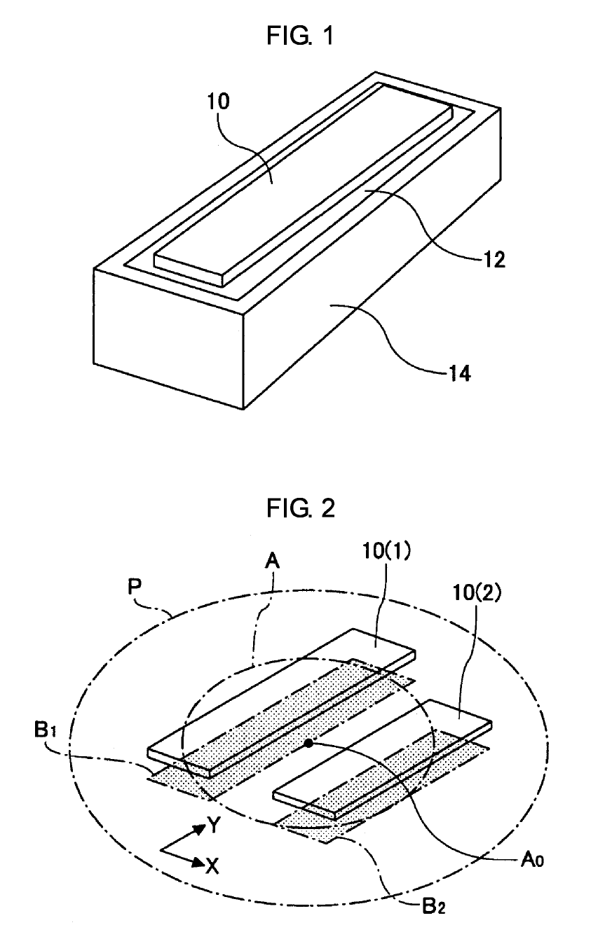

FIG. 1 shows an example of a configuration of a thin and long target used in an embodiment of the present invention. The thin and long target 10 is a thin and long polygonal plate-shaped target formed of an arbitrary material for a thin film (e.g., a metal, an insulating material, or the like). The thin and long target 10 is joined to a backing plate 12 formed of, for example, a copper-based conductor, and the backing plate 12 is attached to one surface of a sputtering gun unit 14. The sputtering gun unit 14 may include a magnetic field generation mechanism including a moving magnet for a magnetron discharge disposed therein or a power feeding mechanism. The sputtering gun unit 14 may be mounted on a magnetron sputtering apparatus and may be driven to emit sputtering particles substantially uniformly per time from a substantially entire surface of the target 10 during a sputtering process.

A principle of a magnetron sputtering method in an embodiment of the present invention will be explained with reference to FIG. 2. In the present embodiment, as shown in FIG. 2, a virtual wafer arrangement surface P having an area larger than an area of a wafer W acting as an object to be processed (hereinafter, referred to as a wafer W) is set to a position facing thin and long targets 10(1) and 10(2) with a predetermined interval between the position and the thin and long targets (typically a position on a rotation stage 22 that will be described later). The wafer arrangement surface P may have an arbitrary shape. Also, a virtual circular reference region A having a diameter 2R (R is a radius of the wafer W) equal to a diameter of the wafer W is set to the wafer arrangement surface P, and a plurality of, for example, 2 virtual thin and long deposition regions B₁ and B₂ each crossing the circular reference region A in a first direction (Y direction in FIG. 2) on the wafer arrangement surface P are set at a predetermined interval in a second direction (X direction in FIG. 2) perpendicular to the first direction (Y direction in FIG. 2).

Here, on the wafer arrangement surface P, the thin and long deposition region B₁ is disposed such that a right side thereof in FIG. 2 in the X direction is in a left half of the circular reference region A to be substantially tangential to a normal line passing through a center Ao of the circular reference region A. Also, the thin and long deposition region B₂ is disposed such that a right side in FIG. 2 in the X direction is in a right half of the circular reference region A to pass through an edge of the circular reference region A. In the X direction, a value obtained by summing widths (X direction size) of the thin and long deposition regions B₁ and B₂ is set to be equal to the radius R of the circular reference region A. In general, each of the widths of the thin and long deposition regions B₁ and B₂ may be set to be R/2. In this case, the interval between the thin and long deposition regions B₁ and B₂ in the X direction is also R/2.

Also, a length of each of the thin and long deposition regions B₁ and B₂ in the Y direction may be any length crossing the circular reference region A or the wafer W. However, in order to reduce material costs, it is preferable that a portion of each of the thin and long deposition regions B₁ and B₂ sticking out of the circular reference region A in the Y direction is as short as possible. In this case, it is preferable that the thin and long deposition region B₁ close to the center Ao of the circular reference region A is relatively long, and the thin and long deposition region B₂ close to the edges of the circular reference region A is relatively short.

Also, one pair of long sides of each of the thin and long deposition regions B₁ and B₂ may be parallel to each other in the first direction, and short sides of each of the thin and long deposition regions B₁ and B₂ may not be parallel to each other in the second direction or may be curved. Also, as will be described later, each of the long sides of each of the thin and long deposition regions B₁ and B₂ may not be straight, and may have a recess portion or a convex portion at one place or a plurality of places thereof.

Also, some of sputtering particles scattered from the target 10 may be incident on a region other than a thin and long deposition region B.

The two thin and long targets 10(1) and 10(2) respectively corresponding to the thin and long deposition regions B₁ and B₂ on the wafer arrangement surface P are disposed to face the thin and long deposition regions B₁ and B₂ such that sputtering particles emitted from surfaces of the targets are incident respectively on the thin and long deposition regions B₁ and B₂. In order to confine the sputtering particles emitted from the thin and long target 10(1) in the thin and long deposition region B₁ and to confine the sputtering particles emitted from the thin and long target 10(2) in the thin and long deposition region B₂, a slit or a collimator may be very appropriately used as will be described later.

(Embodiment 1)

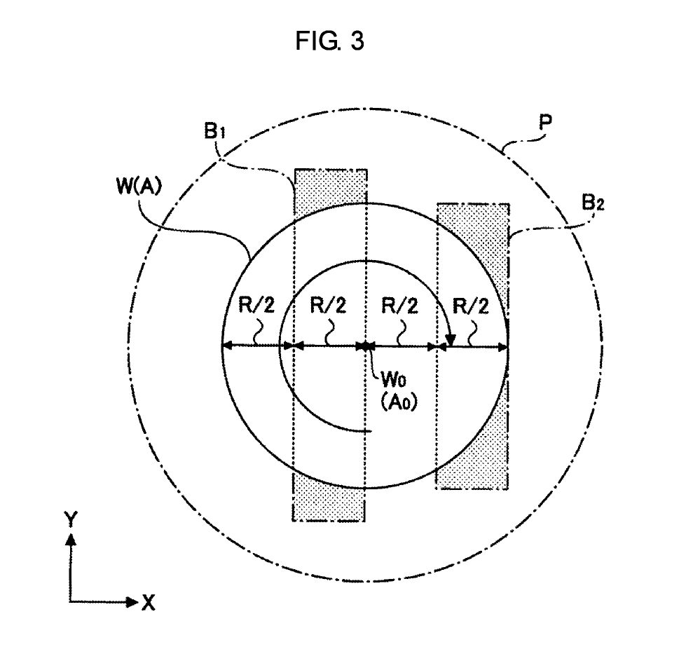

FIG. 3 shows a positional relationship between the wafer W and the portions A, B₁, and B₂ on the wafer arrangement surface P in Embodiment 1 of the present invention. In the present embodiment, the wafer W on which a film is to be deposited exactly overlaps with the circular reference region A on the wafer arrangement surface P. Also, the wafer W rotates at a predetermined rotation speed around the center Ao of the circular reference region A. Due to the rotation, a wafer central portion of the wafer W inner than a radius R/2 is exposed to the sputtering particles from the thin and long target 10(1) only while the wafer central portion passes through the thin and long deposition region B₁, and a wafer outer half region of the wafer W outer than the radius R/2 is exposed to the sputtering particles from the thin and long targets 10(1) and 10(2) while the wafer outer half region passes through the thin and long deposition regions B₁ and B₂. Also, the wafer central portion and the wafer outer half region are not exposed to the sputtering particles when passing through a region other than the thin and long deposition regions B₁ and B₂.

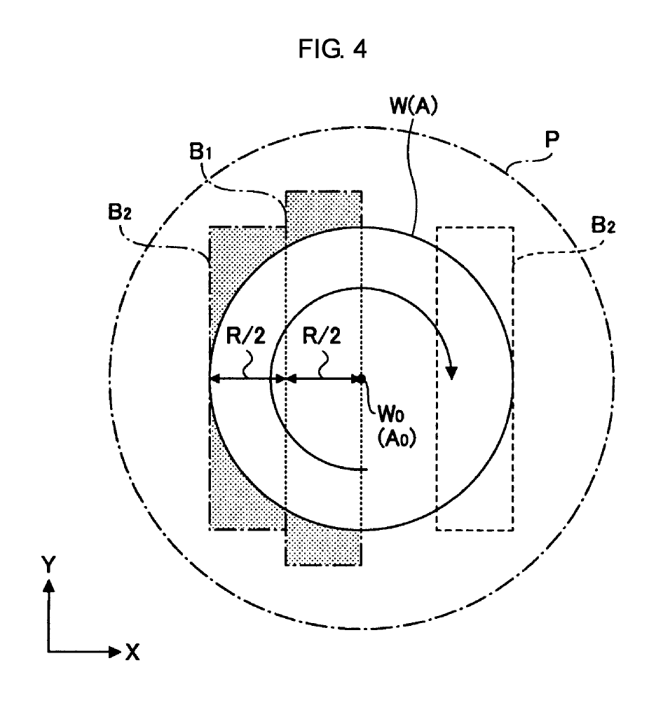

An arrangement relationship (layout) of the portions A, B₁, B₂, and Won the wafer arrangement surface P as shown in FIG. 3 is equal to an arrangement relationship (layout) of the portions A, B₁, B₂, and W on the wafer arrangement surface P as shown in FIG. 4 in terms of sputter film formation. Here, the thin and long deposition region B₂ in the arrangement relationship of FIG. 4 and the thin and long deposition region B₂ in the arrangement relationship of FIG. 3 are point-symmetrical to each other about the center Ao of the circular reference region A. In this case, a left side of the thin and long deposition region B₂ in FIG. 4 in the X direction passes through an edge of the circular reference region A and the other side (right side) of the thin and long deposition region B₂ is tangent to the other side (left side in FIG. 4) of the thin and long deposition region B₁.

In FIG. 4, due to the rotation of the wafer W, the wafer central portion of the wafer W is exposed to the sputtering particles from the thin and long target 10(1) while the wafer central portion passes through a continuous left half (180°) section where only the thin and long deposition region B1 exists, and the wafer outer half region is exposed to the sputtering particles from the thin and long targets 10(1) and 10(2) while the wafer outer half region passes through the continuous left half (180°) section over the thin and long deposition regions B₁ and B₂. The wafer central portion and the wafer outer half region are not exposed to the sputtering particles when passing through a region other than the thin and long deposition regions B₁ and B₂ (a right half (180°) section). Accordingly, theoretically, it is easily understood that when a thin film deposition speed on the thin and long deposition regions B₁ and B₂ is J (nm/min), a film formation rate is J/2 (nm/min) at any position on the wafer W irrespective of the number of rotations of the wafer W.

Even in FIG. 3, since a time for which each portion on a surface of the wafer W is exposed to the sputtering particles from the thin and long targets 10(1) and 10(2) during one rotation and the amount of incident sputtering particles are the same as those in FIG. 4, theoretically it is understood that a film formation rate is J/2 (nm/min) equally at any position on the wafer W.

Also, in FIGS. 3 and 4, a value obtained by summing widths (X direction size) of the thin and long targets 10(1) and 10(2) may be equal to the radius R of the wafer W, and the thin and long targets 10(1) and 10(2) may not have the same width (R/2).

A difference between the layouts shown in FIGS. 3 and 4 results from structural realizations of the rectangular targets 10(1) and 10(2).

That is, in the layout shown in FIG. 4, the thin and long targets 10(1) and 10(2) should be arranged without a gap. However, as shown in FIG. 1, since the thin and long targets 10(1) and 10(2) are supported on the backing plates 12 each having an area larger than that of each of the thin and long targets 10(1) and 10(2) and the backing plates 12 are additionally attached to the sputtering gun units 14 each having an area larger than that of the backing plate 12, it is rather difficult to actually arrange the thin and long targets 10(1) and 10(2) without a gap.

Meanwhile, in the layout shown in FIG. 3, the thin and long deposition regions B₁ and B₂ are disposed with a sufficiently large interval (R/2) therebetween. Accordingly, when the thin and long targets 10(1) and 10(2) are disposed respectively at positions facing the thin and long deposition regions B₁ and B₂, two sputtering gun units 14 may be easily arranged in the X direction.

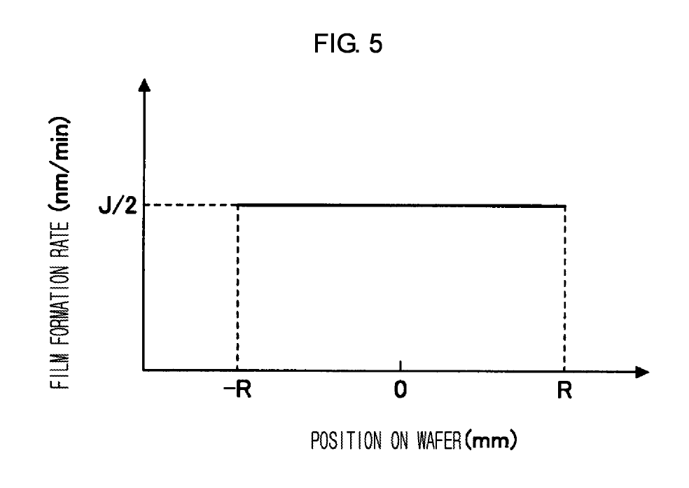

When it is assumed that a film formation rate on the thin and long deposition regions B₁ and B₂ is J (nm/min) uniformly over these regions, a desirable film formation rate distribution on the wafer W is J/2 (nm/min) uniformly in a diameter direction as shown in FIG. 5.

However, in this embodiment (layout of FIG. 3), a very high degree of precision is required in order to actually dispose the thin and long targets 10(1) and 10(2) and the wafer W.

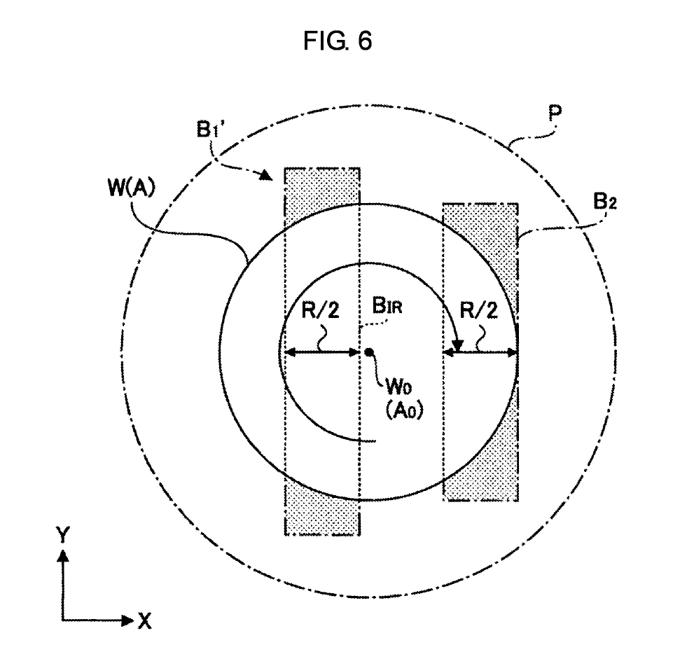

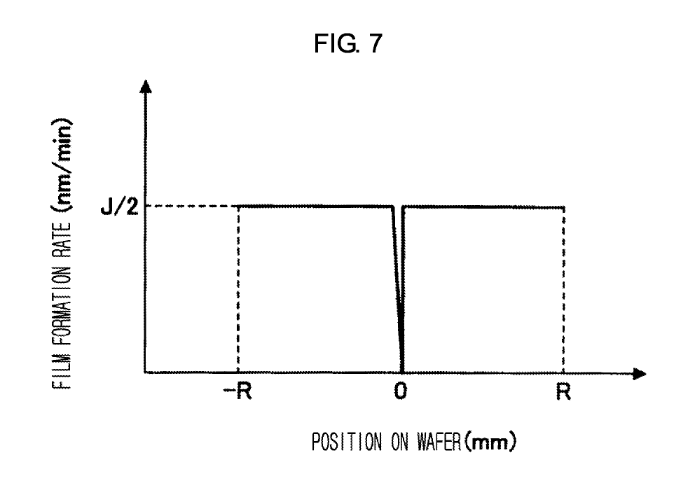

For example, even when the wafer W exactly overlaps with the circular reference region A, if a right side BIR of the thin and long target 10(1) is deviated leftward from the center Ao of the circular reference region A and thus the thin and long deposition region B₁ corresponding to the thin and long target 10(1) is also deviated leftward from the center Ao, as shown in FIG. 6, exposing of a wafer central part (a circular region having a distance between the center Ao and the right side BIR as a radius) to the sputtering particles from the thin and long target 10(1) is difficult, thereby generating a singularity where a film formation rate is abnormally low at the wafer central part as shown in FIG. 7.

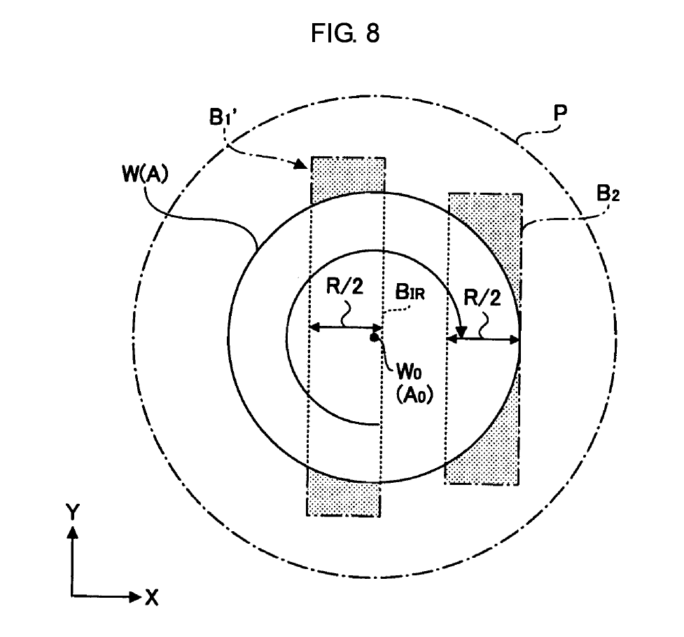

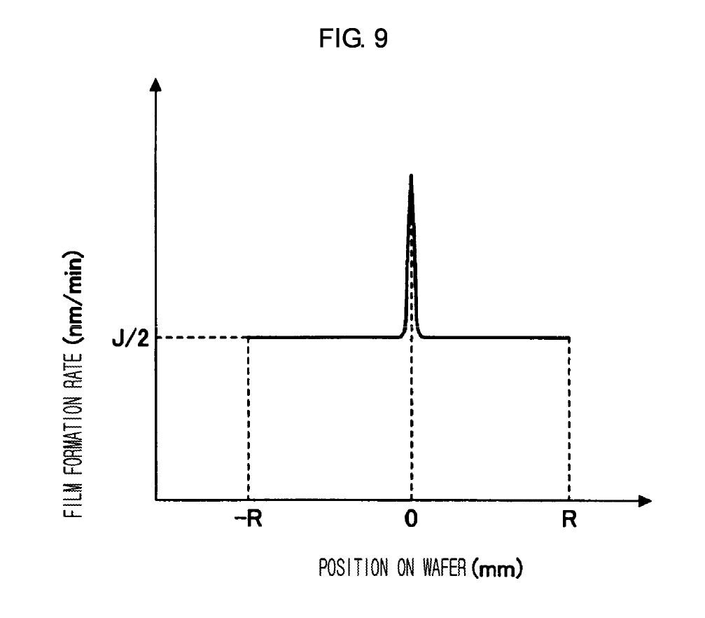

Alternatively, if the right side BIR of the thin and long target 10(1) is deviated rightward from the center Ao of the circular reference region A and thus the thin and long deposition region B1 corresponding to the thin and long target 10(1) is also deviated rightward from the center Ao, as shown in FIG. 8, a wafer central part (a circular region having a distance between the center Ao and the right side BIR as a radius) is continuously exposed to the sputtering particles from the thin and long target 10(1) during the rotation of the wafer W, thereby generating a singularity where a film formation rate is abnormally high at the wafer central part as shown in FIG. 9.

Also, while the thin and long targets 10(1) and 10(2) are precisely disposed, if the wafer W is slightly deviated from the circular reference region A, such a singularity is generated in a film formation rate distribution on the wafer W.

(Embodiment 2)

Next, Embodiment 2 of the present invention where requirements for a high degree of precision in a positional relationship between the rectangular targets 10(1) and 10(2) and the wafer W are relatively reduced when compared with Embodiment 1 will be explained.

Embodiment 2 is almost the same as Embodiment 1 except that the wafer W is disposed on the wafer arrangement surface P such that a center Wo of the wafer W is spaced apart by a predetermined distance a from the center Ao of the circular reference region A and the wafer W is rotated around the center Ao of the circular reference region A.

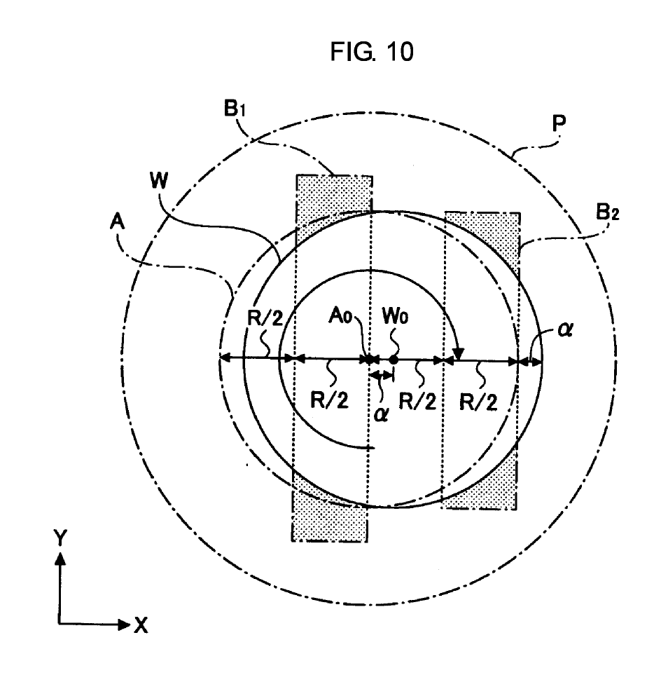

FIGS. 10 through 13 each show a positional relationship between the wafer W and the circular reference region A and the thin and long deposition regions B₁ and B₂ for every ¼)(90°-rotation of the wafer W in Embodiment 2.

FIG. 10 shows a positional relationship when the wafer W is most deviated in a +X direction (rightward in FIG. 10) due to the rotation. As shown in FIG. 10, the center Wo of the wafer W is deviated rightward by the same distance as the distance a from the thin and long deposition region B₁, and a right end of the wafer W sticks out by the same distance as the distance a from the thin and long deposition region B₂.

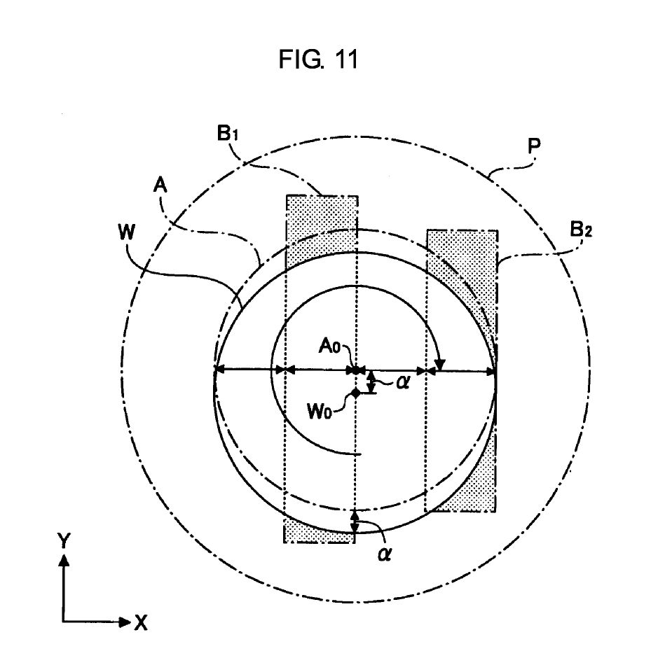

FIG. 11 shows a positional relationship when the wafer W is additionally rotated by ¼ from the position of FIG. 10 and is most deviated in a −Y direction (downward in FIG. 11). As shown in FIG. 11, a lower end of the wafer W does not stick out from the thin and long deposition regions B₁ and B₂ in the Y direction. In the X direction, a relative positional relationship between the wafer W and the thin and long deposition regions B₁ and B₂ is the same as that when the wafer W exactly overlaps with the circular reference region A (see FIG. 3).

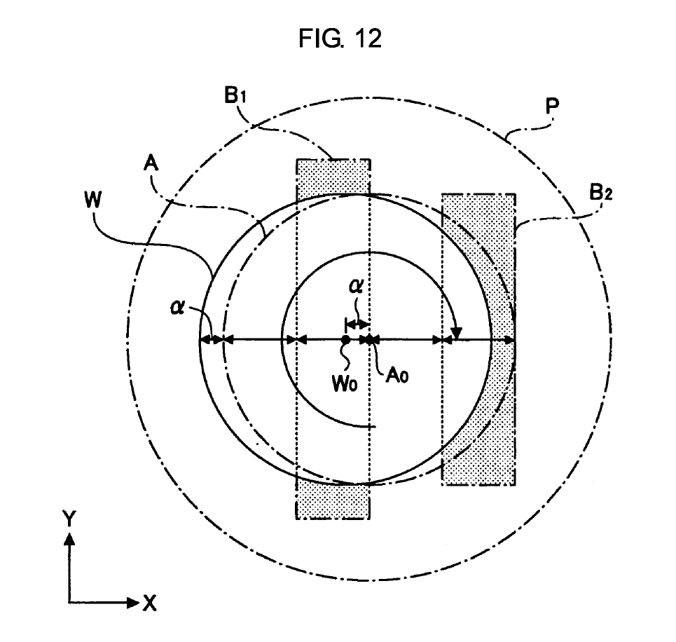

FIG. 12 shows a positional relationship when the wafer W is additionally rotated by ¼ from the position of FIG. 11 and is most deviated in a −X direction (leftward in FIG. 12). As shown in FIG. 12, the center Wo of the wafer W is at an inner position spaced apart by the distance a from a right side of the thin and long deposition region B₁, and a right end of the wafer W is at an inner position spaced apart by the distance a from a right side of the thin and long deposition region B₂.

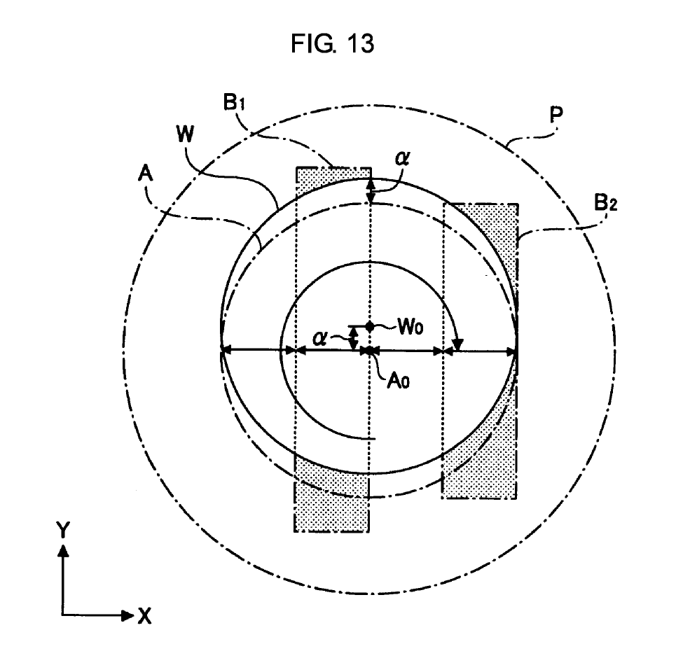

FIG. 13 shows a positional relationship when the wafer W is additionally rotated by ¼ from the position of FIG. 12 and is most deviated in a +Y direction (upward in FIG. 13). As shown in FIG. 13, an upper end of the wafer W does not stick out from the thin and long deposition regions B₁ and B₂ similar to FIG. 11. In the X direction, a relative positional relationship between the wafer W and the thin and long deposition regions B₁ and B₂ is the same as that when the wafer W exactly overlaps with the circular reference region A.

When the wafer W eccentrically rotates as described above, since the center Wo of the wafer W rotates around the center Ao of the circular reference region A with the radius a therebetween, although there is a slight error in a degree of precision for a positional relationship between the circular reference region A and the thin and long deposition regions B₁ and B₂, the center Wo of the wafer W (and a region inner than the radius a) passes through the thin and long deposition region B1 in a substantially 180° section during one rotation of the wafer W. Accordingly, since a film formation rate not different from that in other portions is obtained even at a part around the center Wo of the wafer W, such a singularity in a film formation rate distribution on the wafer W as described above can be surely prevented.

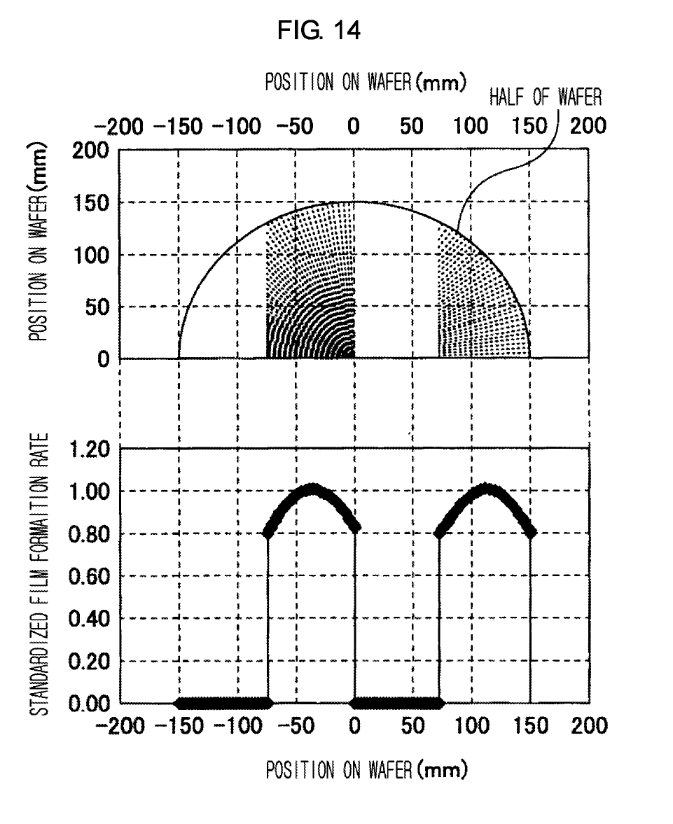

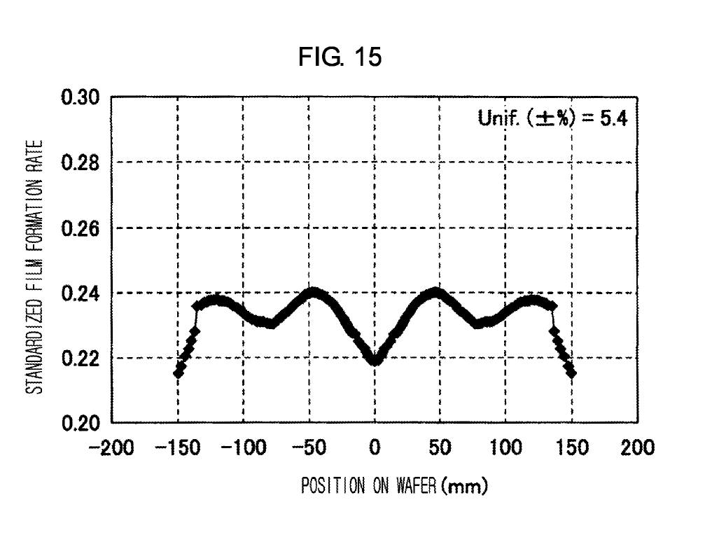

FIGS. 14 and 15 show a specific simulation (calculation) result in Embodiment 2. In the simulation, the wafer W having a diameter of 300 mm was set as an object to be processed and each of widths of the thin and long deposition regions B₁ and B₂ was set to be 75 mm (R/2). In this case, as shown in FIG. 14, there are two deposition regions on the wafer W in the X direction (−75 mm□0 mm, and 75 mm□150 mm) at any time during a rotation of the wafer W. Here, it was assumed that film formation rates on the thin and long deposition regions B₁ and B₂ in the X direction are not uniform and are distributed as a quadratic function, and a ratio E/C between a film formation rate on a central portion and a film formation rate on an end portion in this case is 0.8. Also, an eccentric amount a was set to 15 mm.

Under the aforesaid conditions, in order to obtain an average value (an approximate value) of a film formation rate distribution in an eccentric rotation of the wafer W, when a standardized film formation rate distribution on the wafer W on the assumption that the wafer W rotates while having the positions shown in FIGS. 10 through 13 was calculated, such a profile as shown in FIG. 15 was obtained. In the profile, an in-plane uniformity was ±5.4%.

(Embodiment 3)

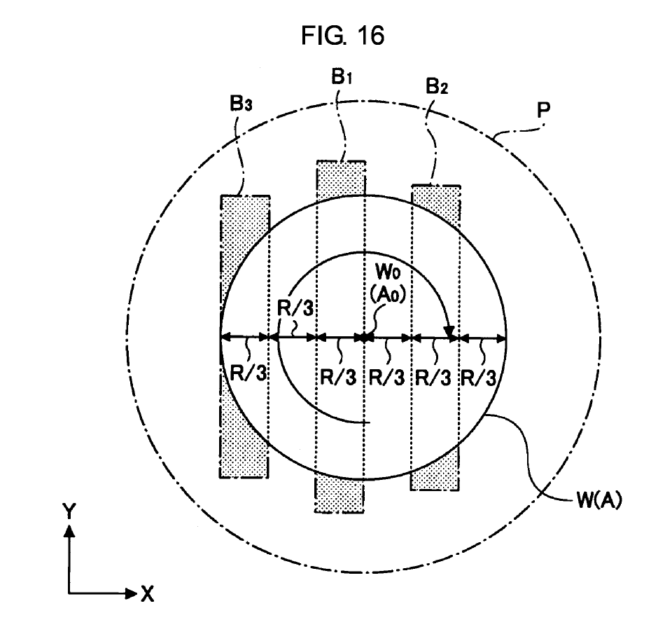

Embodiment 3 of the present invention will now be explained with reference to FIGS. 16 through 18.

In Embodiment 3, as shown in FIG. 16, three thin and long deposition regions B₁, B₂, and B₃ are set on the wafer arrangement surface P. The thin and long deposition regions B₁, B₂, and B₃ are arranged in parallel at predetermined intervals in the X direction, and each cross the circular reference region A in the Y direction.

The thin and long deposition region B₁ is disposed such that in a left region of the circular reference region A, a side in a +X direction (right side in FIG. 16) of the thin and long deposition region B₁ passes through the center Ao of the circular reference region A. Also, the thin and long deposition region B₃ is disposed such that in the left region of the circular reference region A, a side in a −X direction (left side in FIG. 16) of the thin and long deposition region B₃ passes through edges of the circular reference region A. Meanwhile, the thin and long deposition region B₂ is disposed such that when the thin and long deposition region B₂ is moved to a position in the left region of the circular reference region A, that is point-symmetrical to the thin and long deposition region B₂ about the center Ao of the circular reference region A, the moved thin and long deposition region B₂ is inserted between the thin and long deposition regions B₁ and B₃ without a gap, and thus the left region of the circular reference region A is almost entirely covered by the thin and long deposition regions B₁, B₂, and B₃.

Each of widths of the thin and long deposition regions B₁, B₂, and B₃ in the X direction is arbitrarily determined as long as a value obtained by summing the widths of the thin and long deposition regions B₁, B₂, and B₃ in the X direction is equal to the radius R of the wafer W. For example, each of the widths of the thin and long deposition regions B₁, B₂, and B₃ in the X direction may be equally R/3.

Although not shown, three thin and long targets 10(1), 10(2), and 10(3) respectively facing the three thin and long deposition regions B₁, B₂, and B₃ are disposed over the wafer arrangement surface P. Accordingly, the sputtering particles emitted from the thin and long target 10(1) may be mainly confined in the thin and long deposition region B₁, the sputtering particles emitted from the thin and long target 10(2) may be mainly confined in the thin and long deposition region B₂, and sputtering particles emitted from the thin and long target 10(3) may be mainly confined in the thin and long deposition region B₃.

Referring to FIG. 16, like in Embodiment 1 (see FIG. 3), the wafer W exactly overlaps with the circular reference region A (eccentric amount α=0). In this case, the wafer W rotates around the center Ao of the circular reference region A. Of course, the center Wo of the wafer W may be deviated from the center Ao of the circular reference region A, and thus the wafer W may eccentrically rotate with respect to the circular reference region A.

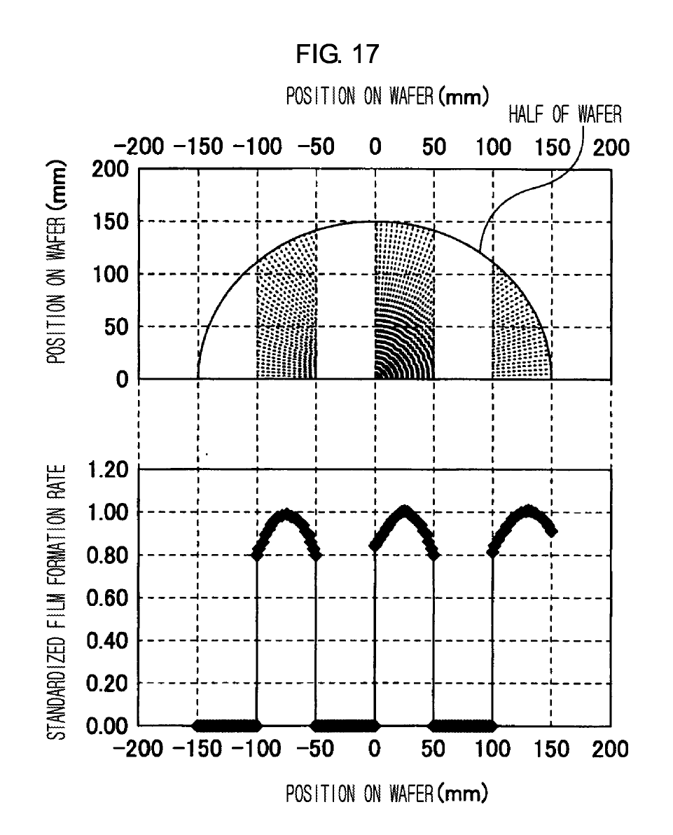

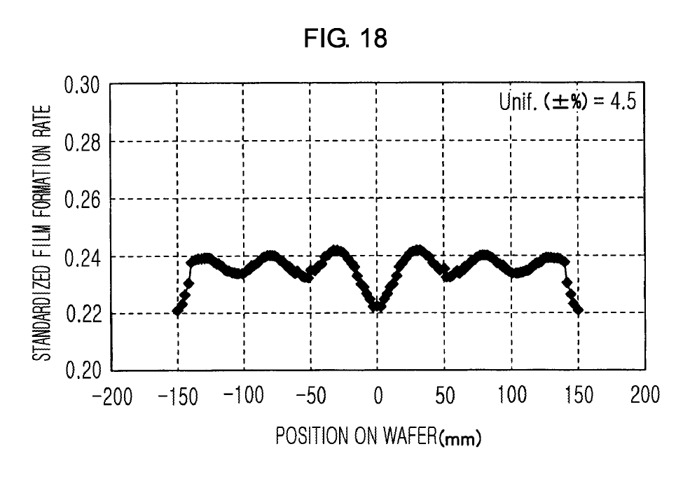

FIGS. 17 and 18 show a specific simulation (calculation) result in Embodiment 3. In the simulation, the wafer W having a diameter of 300 mm was set as an object to be processed, and each of widths of the thin and long deposition regions B₁, B₂, and B₃ was set to 50 mm (R/3). In this case, as shown in FIG. 17, there are three deposition regions on the wafer W in the X direction (−100 mm□−50 mm, 0 mm□50 mm, and 100 mm□150 mm) at any time during a rotation of the wafer W. Here, it was assumed that film formation rates on the thin and long deposition regions B₁, B₂, and B₃ in the X direction are not uniform and a ratio E/C between a film formation rate on a central portion and a film formation rate on an end portion in this case is 0.8. Also, an eccentric amount a was set to 10 mm.

Under the aforesaid conditions, in order to obtain an average value (an approximate value) of a film formation rate distribution in an eccentric rotation of the wafer W, when a standardized film formation rate distribution on the wafer W on the assumption that the wafer W rotates while having the positions shown in FIGS. 10 through 13 was calculated, such a profile as shown in FIG. 18 was obtained. In the profile, an in-plane uniformity was improved to ±4.5%.

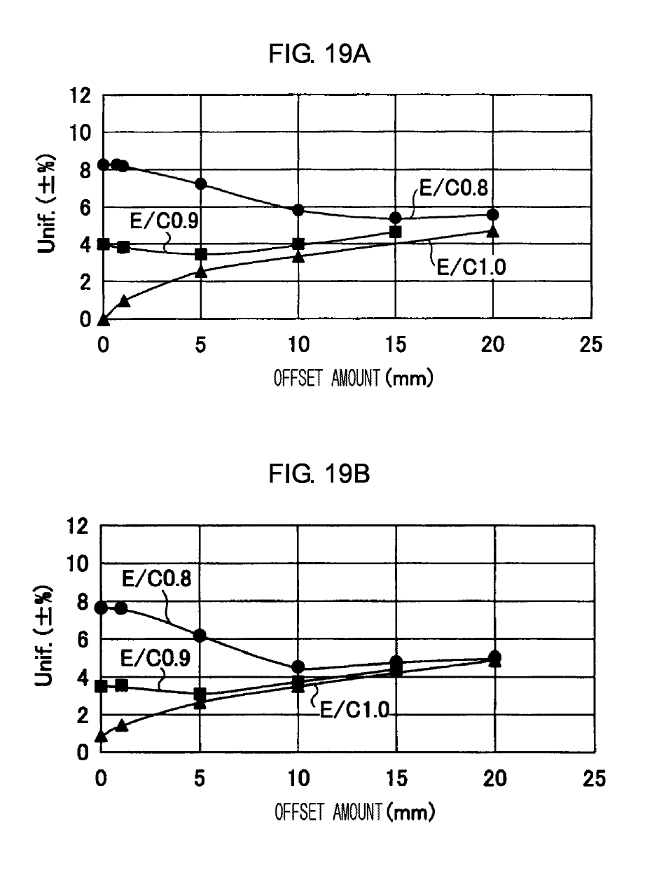

FIG. 19A is a graph showing dependence on an eccentric amount a in a standardized film formation rate distribution when two targets in Embodiment 2 are used (hereinafter, referred to as a 2-target method). FIG. 19B is a graph showing dependence on an eccentric amount a in a standardized film formation rate distribution when three targets in Embodiment 3 are used (hereinafter, referred to as a 3-target method). In the graphs, a ratio E/C between film formation rates on a central portion and an end portion in each of the thin and long deposition regions B₁, B₂, and B₃ was a parameter. In detail, the ratio E/C was 0.8, 0.9, and 1.0. Also, an eccentric amount a of an eccentric rotation of a wafer was changed every 5 mm in a range of 0 to 20 mm.

When E/C=0.8, in the case of a 2-target method, as shown in FIG. 19A, an in-plane uniformity is greatest (about ±8.0%) when α=0, is monotonously decreased as the eccentric amount a is increased, is lowest (about ±5.5%) when the eccentric amount a is about 15 mm, and then is slowly increased. In the case of a 3-target method, as shown in FIG. 19B, an in-plane uniformity is greatest (about ±7.8%) when α=0, is monotonously decreased as the eccentric amount a is increased, is lowest (about ±4.5%) when the eccentric amount a is about 10 mm, and then is slowly increased.

When E/C=0.9, in the case of a 2-target method, as shown in FIG. 19A, an in-plane uniformity is a considerably low value (about ±4.0%) when α=0, is decreased as the eccentric amount a is increased, is lowest (about ±3.5%) when the eccentric amount a is about 5 mm, then is slowly increased, and is about ±5.5% when the eccentric amount a is about 15 mm. Even in the case of a 3-target method, as shown in FIG. 19B, an in-plane uniformity is a considerably low value (about ±3.8%) when α=0, is decreased as the eccentric amount a is increased, is lowest (about ±3.0%) when the eccentric amount a is about 5 mm, then is gradually increased, and is about ±3.8% when the eccentric amount a is about 10 mm.

When E/C=1.0, in the case of a 2-target method, as shown in FIG. 19A, an in-plane uniformity is almost ±0 when α=0, is substantially linearly increased as the eccentric amount a is increased, and is about ±4.0% when the eccentric amount a is about 15 mm. In the case of a 3-target method, as shown in FIG. 19B, an in-plane uniformity is an extremely low value (about ±1.0%) when α=0, is substantially linearly increased as the eccentric amount a is increased, and is about ±3.5% when the eccentric amount a is about 10 mm.

It is found from FIGS. 19A and 19B that it is preferable that in order to achieve a stable in-plane uniformity with a lowest dependence on E/C, the eccentric amount a is set to be about 15 mm in the case of a 2-target method and is set to be about 10 mm in the case of a 3-target method.

In the case of a 3-target method, it is preferable that a gap between the three thin and long targets 10(1), 10(2), and 10(3) is relatively large. In this regard, while it is difficult to achieve a large interval when α=15 mm, a sufficiently large interval is achieved when α=10 mm.

When the wafer W eccentrically rotates as described above in the second and third embodiments, since a positional relationship between the wafer W and the thin and long deposition regions B₁ and B₂ or a positional relationship between the wafer W and the thin and long deposition regions B₁, B₂ and B₃ is different from a desirable positional relationship shown in FIG. 4, film formation rates on a wafer central portion and a wafer circumferential portion are decreased as shown in FIGS. 15 and 18.

(Embodiment 4)

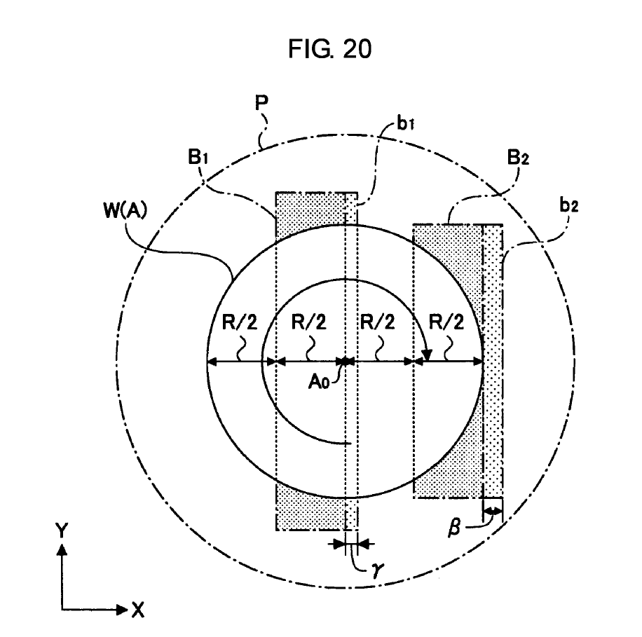

Embodiment 4 of the present invention will now be explained with reference to FIG. 20 through 23. In the present embodiment, when compared with Embodiment 3, a decrease in film formation rate distribution characteristics on a wafer central portion and a wafer circumferential portion is reduced, thereby further improving an in-plane uniformity.

In Embodiment 4, as shown in FIG. 20, in the case of a 2-target method, the thin and long deposition region B₁ is disposed such that the center Ao of the circular reference region A is located at a position inner than a right side b1 of the thin and long deposition region B₁. A distance in the X direction between the center Ao of the circular reference region A and the right side b1 of the thin and long deposition region B₁ is γ. Also, the thin and long deposition region B₂ is disposed such that the edge of the circular reference region A in a +X direction are located at a position inner than a right side b2 of the thin and long deposition region B₂. A distance in the X direction between the edge of the circular reference region A in the +X direction and the right side b2 of the thin and long deposition region B₂ is R. A value obtained by summing widths of the thin and long deposition regions B₁ and B₂ in the X direction is set to be greater by a predetermined length A (=γ+β) than the radius R of the circular reference region A. In other words, in the layouts of FIGS. 3, and 10 through 13, when a width of the slender deposition B₁ in the X direction is increased by γ in the +X direction and a width of the thin and long deposition region B₂ is increased by β in the +X direction, a layout of FIG. 20 is achieved. Also, it is preferable that α=β.

Also, although not shown, members for defining each of the thin and long deposition regions B₁ and B₂ (for example, slits 60(1) and 601(2) that will be described later) may be provided such that the sputtering particles emitted from the thin and long targets 10(1) and 10(2) are confined respectively mainly in the thin and long deposition regions B₁ and B₂ each having an increased width. Also, a shape and a size of each member may be determined in accordance with those of the thin and long deposition regions B₁and B₂.

As shown in FIG. 20, in Embodiment 4, like in Embodiment 2, the wafer W may be slightly moved from the circular reference region A, and eccentrically rotate (eccentric amount α=15 mm).

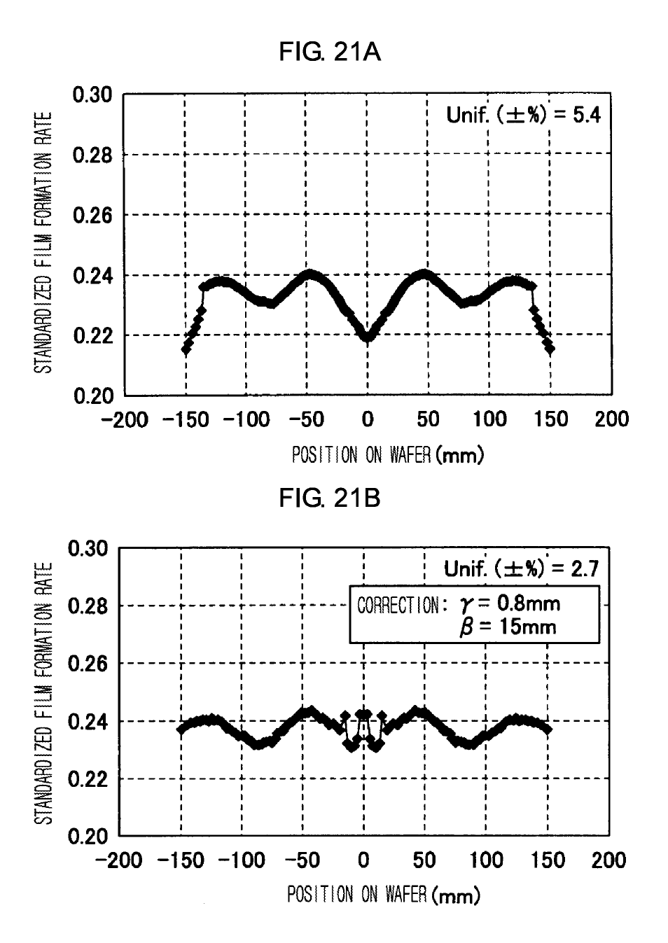

In Embodiment 4, when a simulation was performed with respect to a 2-target method under the same conditions as those in Embodiment 2, as shown in FIG. 21B, there is little decrease in film formation rate distribution characteristics on a wafer central portion and a wafer circumferential portion, thereby greatly improving an in-plane uniformity to ±2.7%. Also, FIG. 21A shows the simulation result in Embodiment 2 for comparison (see FIG. 15).

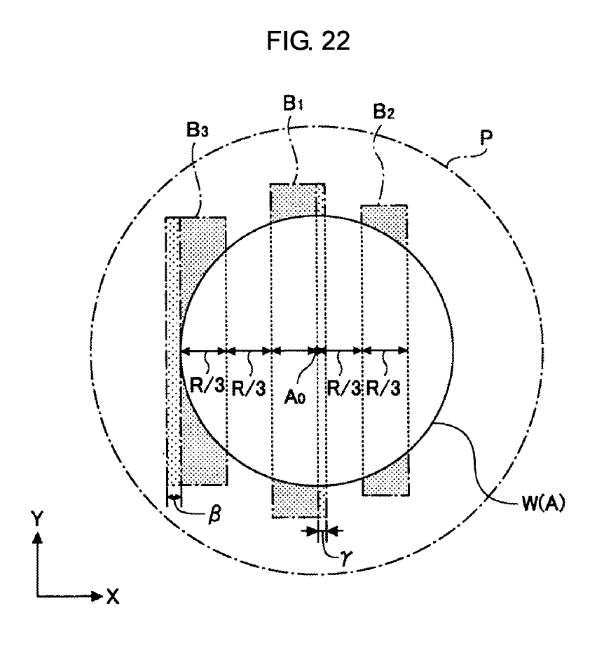

FIG. 22 shows a layout of a 3-target method in Embodiment 4. As shown in FIG. 22, the thin and long deposition region B₁ is disposed such that the center Ao of the circular reference region A is located at a position inner than a right side b1 of the thin and long deposition region B₁. A distance between the center Ao of the circular reference region A and the right side b1 of the thin and long deposition region B₁ is γ. Also, the thin and long deposition region B₃ is disposed such that the edge of the circular reference region A in a −X direction is located at a position inner than a left side b3 of the thin and long deposition region B₃. A distance in the X direction between the edge of the circular reference region A in the −X direction and the left side b3 of the thin and long deposition region B₃ is β. The thin and long deposition region B₂ is disposed such that when the thin and long deposition region B₂ is moved to a position that is point-symmetrical to the thin and long deposition region B₂ about the center Ao of the circular reference region A, the thin and long deposition region B₂ is inserted between the thin and long deposition regions B₁ and B₃ without a gap, and thus a left half of the circular reference region A is covered by the thin and long deposition regions B₁, B₂, and B₃. The thin and long deposition region B₂ is disposed almost in a middle region in the X direction in a right half region of the circular reference region A.

In other words, in the layout of FIG. 16, when a width of the thin and long deposition region B₁ in the X direction is increased rightward by γ and a width of the thin and long deposition region B₃ is increased leftward by R, the layout of FIG. 22 is achieved.

Also, although not shown, members for defining each of the thin and long deposition regions B₁, B₂, and B₃ (for example, the slits 60(1), 60(2) and the like, which will be explained later) may be provided such that the sputtering particles emitted from the thin and long targets 10(1), 10(2), and 10(3) are confined respectively mainly in the thin and long deposition regions B₁, B₂, and B₃. Also, a shape and a size of each member may be determined in accordance with those of the thin and long deposition regions B₁, B₂, and B₃.

As shown in FIG. 22, in Embodiment 4, like in Embodiment 3 (FIG. 16), the wafer W exactly overlaps with the circular reference region A (eccentric amount α=0), and rotates around the center Ao of the circular reference region A. Of course, the wafer W may be slightly moved from the circular reference region A and eccentrically rotate.

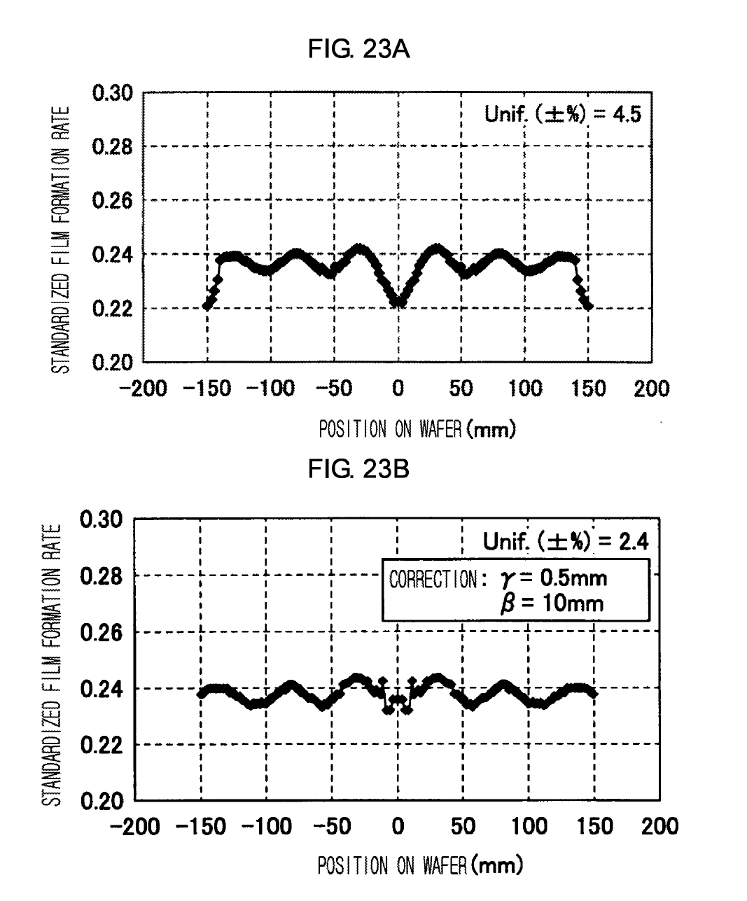

In Embodiment 4, when a simulation was performed with respect to a 3-target method under the same conditions as those in Embodiment 3, as shown in FIG. 23B, there is little decrease in film formation rate distribution characteristics on a wafer central portion and a wafer circumferential portion, thereby greatly improving an in-plane uniformity to ±2.4%. Also, FIG. 23A shows the simulation result in Embodiment 3 for comparison (FIG. 18).

(Embodiment 5)

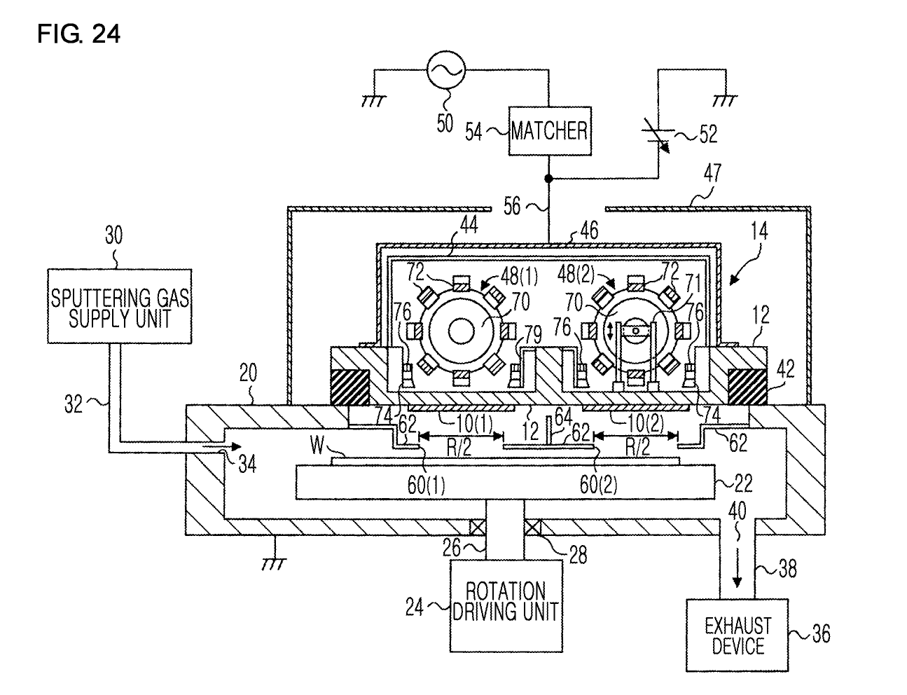

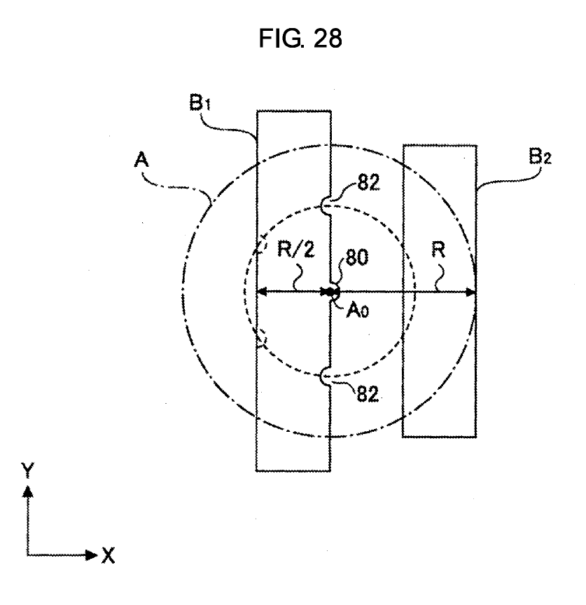

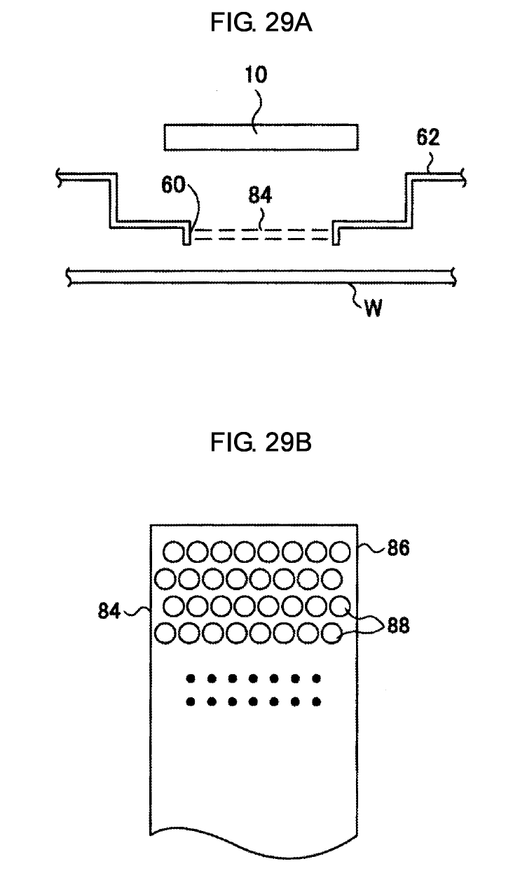

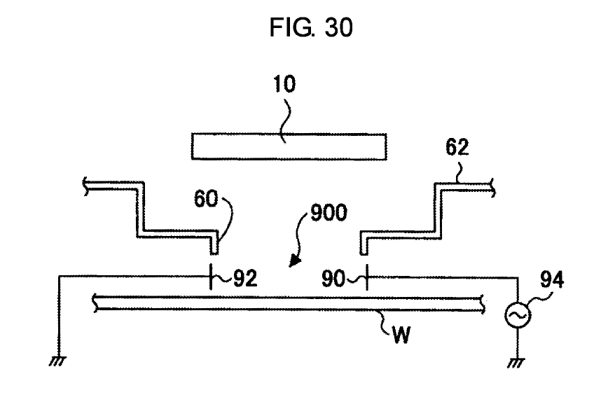

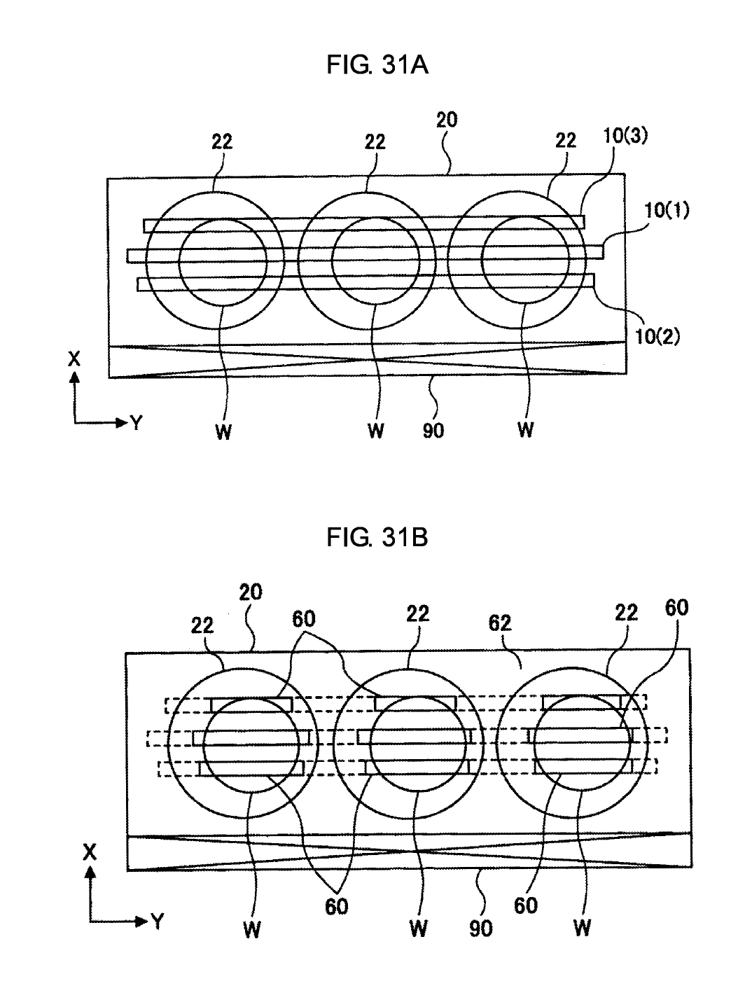

A magnetron sputtering apparatus in an embodiment of the present invention will now be explained with reference to FIGS. 24 through 29. The magnetron sputtering apparatus uses a 2-target method.

As shown in FIG. 24, the magnetron sputtering apparatus includes a rotation stage 22, on which the wafer W is held, provided in a middle region of a chamber 20 that is pressurizable. The chamber 20 is formed of a conductor such as aluminum or the like, and is grounded. The rotation stage 22 is connected to a rotation driving unit 24 disposed outside (under) the chamber 20 with a rotation driving shaft 26 therebetween, and may rotate at a desired rotation speed due to a rotation driving force of the rotation driving unit 24. A shaft support 28 that allows the rotation driving shaft 26 to rotatably and airtightly pass therethrough is attached to a bottom wall of the chamber 20.

In the magnetron sputtering apparatus, the wafer arrangement surface P on a top surface of the rotation stage 22, and the thin and long deposition regions B₁ and B₂ and the circular reference region A on the wafer arrangement surface P described above may be set. In this case, the center Ao of the circular reference region A may coincide with a center of the rotation stage 22. However, while the top surface of the rotation stage 22 is movable (rotatable), the wafer arrangement surface P, the circular reference region A, and the thin and long deposition regions B₁ and B₂ are virtual fixed regions.

A gas supply hole 34 connected to a gas supply pipe 32 from a sputtering gas supply unit 30 is formed in a side wall of the chamber 20. Also, although not shown, an opening/closing inlet/outlet for transferring the wafer W to/from the chamber 20 is provided in the side wall of the chamber 20. An exhaust port 40 connected to an exhaust pipe 38 guided to an exhaust device 36 is provided in the bottom wall of the chamber 20.

On a ceiling of the chamber 20, two targets 10(1) and 10(2) are arranged on a target attached surface (a lower surface in FIG. 24) of one (common) backing plate 12. Here, sizes and positions of the targets 10(1) and 10(2) may be determined according to sizes and positions of the thin and long deposition regions B₁ and B₂ set on the wafer arrangement surface P in Embodiments 1 through 4.

The backing plate 12 is attached to the ceiling of the chamber 20 to close an opening of a top surface opening of the chamber 20 with a ring-shaped insulator 42 therebetween. Although not shown, a path through which a cooling medium supplied from a chiller device or the like flows is provided in the back plate 12.

Two magnet units 48(1) and 48(2) for forming a leakage magnetic field for a magnetron discharge on surfaces (lower surfaces) of the targets 10(1) and 10(2) are received in a common inner housing 44 and a common outer housing 46 at a rear side (upper side in FIG. 24) of the backing plate 12. Configurations and operations of the magnet units 48(1) and 48(2) will be explained later.

The inner housing 44 is formed of a magnetic body, such as, an iron plate, and acts as a magnetic shield for confining a magnetic field generated by the magnet units 48(1) and 48(2) in the housing and preventing (shielding) effects of an ambient external magnetic field. The outer housing 46 is formed of a metal having high electrical conductivity, such as a copper plate, and serves as a power feeding path for applying a high frequency voltage from a high frequency power source 50 and/or a DC voltage from a direct current power source 52, which will be explained later, to the backing plate 12 and the targets 10(1) and 10(2). A protective cover 47 covering the outer housing 46 is formed of a conductive plate, and is grounded with the chamber 20 therebetween.

Another housing for receiving the inner housing 44, the outer housing 46, the magnet units 48(1) and 48(2), and so on may be airtightly attached to the chamber 20 and may be depressurized by using a vacuum pump (not shown). In this configuration, since a pressure (back pressure) applied to the backing plate 12 is dramatically reduced, a thickness of the backing plate 12 can be reduced, and thus a strength of a magnetic field on surfaces of the targets can be increased by accordingly reducing a distance between the magnet units 48(1) and 48(2) and the targets 10(1) and 10(2).

Also, as shown in FIG. 24, a mechanism 71 for supporting the magnet units 48(1) and 48(2) and adjusting heights of the magnet units 48(1) and 48(2) may be provided.

Accordingly, a strength of a magnetic field on the surfaces of the targets 10(1) and 10(2) can be constantly maintained by adjusting a distance between the targets 10(1) and 10(2) and the magnet units 48(1) and 48(2) according to a degree of erosion on the surfaces of the targets. Also, in FIG. 24, the mechanism 71 is provided only on the magnet unit 48(2) for convenience of illustration.

The high frequency power source 50 is electrically connected to the backing plate 12 with a matcher 54, a power feeding line (or a power feeding bar) 56, and the outer housing 46 therebetween. The direct current power source 52 is electrically connected to the backing plate 12 with the power feeding line 56 and the outer housing 46 therebetween. In general, when the targets 10(1) and 10(2) are dielectrics, only the high frequency power source 50 is used. When the targets 10(1) and 10(2) are metals, only the direct current power source 52 is used or both the direct current power source 52 and the high frequency power source 50 are used.

In the chamber 20, a plate body 62 having the aforesaid slits 60(1) and 60(2) corresponding in terms of shape, size, and position to the thin and long deposition regions B₁ and B₂ on the aforesaid wafer arrangement surface P is disposed between the targets 10(1) and 10(2) and the rotation stage 22. When a width of each of the thin and long deposition regions B₁ and B₂ in the X direction is equally set to R/2, a width of each of the slits 60(1) and 60(2) in the same direction may be set to R/2. By disposing the slits 60(1) and 60(2) to be close to the rotation stage 22, the sputtering particles from the targets 10(1) and 10(2) can be additionally confined respectively in the thin and long deposition regions B₁ and B₂.

The plate body 62 in which the slits 60(1) and 60(2) are formed is formed of a conductor such as aluminum or the like, is physically and electrically connected to the chamber 20, and includes a partition plate 64 for isolating sputter emission spaces corresponding to the targets 10(1) and 10(2) from each other.

In the magnetron sputtering apparatus, the wafer W is determined to be located at a predetermined position on the rotation stage 22, that is, at a position exactly overlapping with the circular reference region A or a position deviated by a predetermined distance therefrom. A wafer fixing portion (not shown) for fixing the wafer W on the rotation stage 22 during a rotation is provided on the rotation stage 22.

When a film is deposited on the wafer W by sputtering, a sputtering gas is introduced at a predetermined flow rate into the chamber 20, which is in a sealed state, from the sputtering gas supply unit 30, and the chamber 20 is set to be under a predetermined pressure by the exhaust device 36. Also, by turning on the high frequency power source 50 and/or the direct current power source 52, a high frequency voltage (for example, 13.56 MHz) and/or a direct current voltage is applied as predetermined power to the targets 10(1) and 10(2) of a cathode.

Also, by turning on a magnetic field generation mechanism of the magnet units 48(1) and 48(2), a plasma with a ring shape generated by a magnetron discharge is confined around surfaces of the targets 10(1) and 10(2), and the ring-shaped plasma (plasma ring) is moved in a predetermined direction (a lengthwise direction of the target, that is, Y direction). The sputtering particles emitted from the surfaces of the targets 10(1) and 10(2) due to ion incidence from the plasma ring pass through the corresponding slits 60(1) and 60(2) and scatter toward the virtual thin and long deposition regions B₁ and B₂ set on the rotation stage 22.

Meanwhile, by turning on the rotation driving unit 24, the rotation stage 22 rotates at a predetermined rotation speed (for example, 6 to 60 rpm). In this case, if the center of the wafer W and a rotation center of the rotation stage 22 coincide with each other, the wafer W rotates coaxially with the rotation stage 22. If the center of the wafer W is moved by an eccentric amount a from the rotation center of the rotation stage 22, the wafer W eccentrically rotates.

Due to the above operation, the magnetron sputtering method according to the embodiments of the present invention is performed in the chamber 20, and the sputtering particles are deposited on a surface of the wafer W on the rotation stage 22 to form a desired film.

Also, the sputtering particles scattered toward the thin and long deposition regions B₁ and B₂ and reaching a region outside the wafer W are incident on the top surface of the rotation stage 22, and are deposited on the top surface of the rotation stage 22. In order to prevent deposition on the top surface of the rotation stage 22, a detachable cover may be disposed on the rotation stage 22 to surround the wafer W.

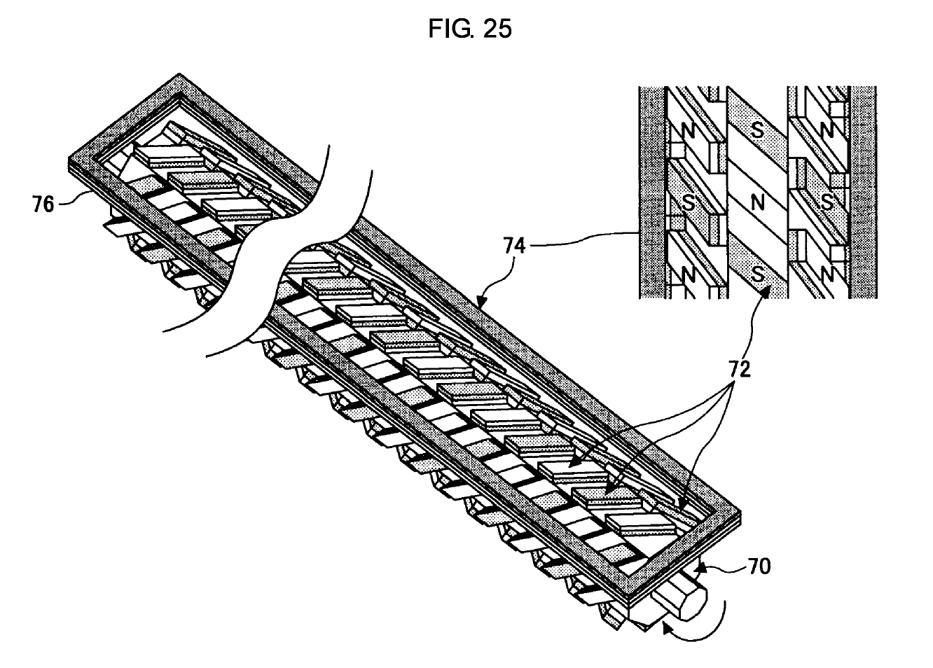

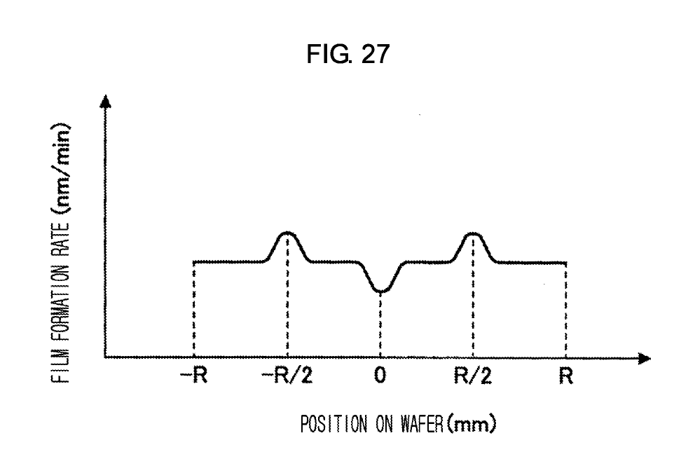

Configurations and operations of the magnet units 48(1) and 48(2) will now be explained with reference to FIGS. 25 and 27. Since the magnet units 48(1) and 48(2) have substantially the same configuration and operation except for their sizes, the magnet units 48(1) and 48(2) are referred to as a magnet unit 48 hereinafter.

FIG. 25 is a perspective view of a columnar rotary shaft 70, a group of a plurality of plate magnets 72, a fixed outer circumferential plate magnet 74, and a paramagnetic body 76, and a plan view thereof as seen from the backing plate 12.

The columnar rotary shaft 70 is formed of, for example, an Ni—Fe-based alloy having high permeabillity, is connected to a motor with a transmission (not shown) therebetween, and rotates at a desired rotation speed (for example, 600 rpm).

An outer circumferential surface of the columnar rotary shaft 70 has a polygonal shape, for example, an octagonal shape, and the plurality of plate magnets 72 each having a parallelogram shape are attached to each surface of the octagonal shape to have a predetermined arrangement. The plate magnets 72 are, preferably, Sm—Co-based sintered magnets having a residual magnetic flux density of about 1.1 T or Nd—Fe—B-based sintered magnets having a residual magnetic flux density of about 1.3 T. The plate magnets 72 are magnetized in a direction perpendicular to a plate surface (plate thickness direction), and are attached spirally to the columnar rotary shaft 70 to form two spirals. The spirals adjacent in an axial direction of the columnar rotary shaft 70 have different magnetic poles in a diameter direction facing away from the columnar rotary shaft 70. In other words, it looks like two band-shaped magnets are wound in a spiral shape along an outer circumferential surface of the columnar rotary shaft 70 such that from among the two band-shaped magnets, one magnet has an N-pole surface and another magnet has an S-pole surface. Accordingly, the N-pole and the S-pole are alternately arranged on one surface of the columnar rotary shaft 70.

As shown in FIG. 24, above the backing plate 12, the fixed outer circumferential plate magnet 74 has a frame shape surrounding the group of the rotation magnets 72, and a surface of the fixed outer circumferential plate magnet 74 facing the backing plate 12 has the S-pole and an opposite surface of the fixed outer circumferential plate magnet 74 has the N-pole. The fixed outer circumferential plate magnet 74 may also be, for example, an Nd—Fe—B-based sintered magnet.

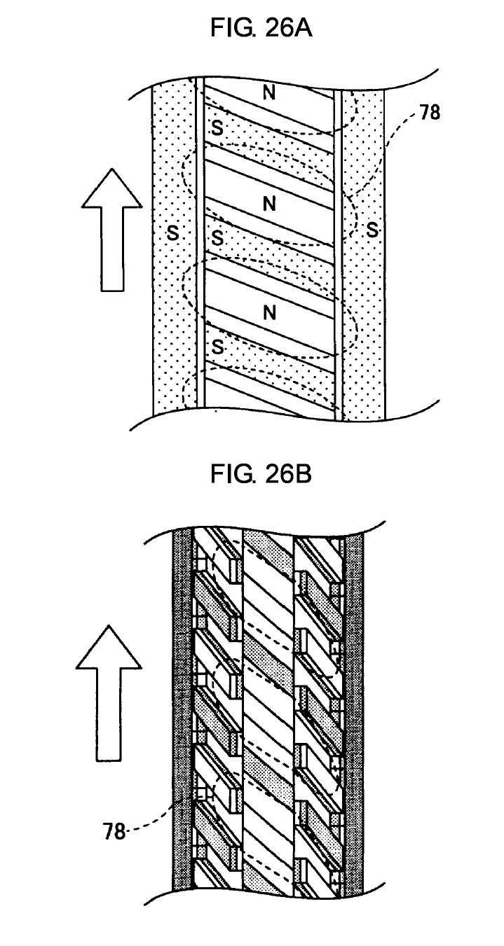

When the plurality of plate magnets 72 are arranged in a spiral shape on the columnar rotary shaft 70 as described above, as shown in FIG. 26A, when seen from the target 10, the N-poles of the plate magnets 72 each having a parallelogram shape are almost surrounded by the S-poles of the plate magnets 72 and the fixed outer circumferential plate magnet 74. Accordingly, part of a line of magnetic force output from the N-poles of the plate magnets 72 passes through the backing plate 12 and the target 10 while being curved, and passes back through the backing plate 12 and the target 10 in an opposite direction, and ends at the S-poles around the plate magnets 72 having the N-poles. A horizontal component of a leakage magnetic field on a surface of the target 10 helps secondary electrons to be captured due to a Lorentz force.

In the magnet unit 48 configured as described above, secondary electrons or a plasma can be confined in an oval loop-shaped pattern 78 as indicated by a dotted line in FIGS. 26A and 26B on the surface of the target 10, and a plurality of plasma rings having the same shape can be generated in an axial direction. Each of the plasma rings has a major axis according to a width of the fixed outer circumferential plate magnet 74 and a minor axis according to a spiral pitch. Accordingly, by setting the width of the fixed outer circumferential plate magnet 74 according to a width of the target 10, sizes of the plasma rings may be adjusted such that major axes of the plasma rings cover from one end to another end of the target 10. By rotating the columnar rotary shaft 70, in a travel direction according to a rotation direction of the columnar rotary shaft 70, each plasma ring may be moved in the axial direction, that is, the lengthwise direction of the target, at a travel speed according to a rotation speed. Accordingly, almost an entire surface of the target can be sputtered.

Referring back to FIG. 24, the fixed outer circumferential paramagnetic body 76 having the same shape as the fixed outer circumferential plate magnet 74 is attached onto the fixed outer circumferential plate magnet 74, and the fixed outer circumferential paramagnetic body 76 is connected to the inner housing 44 with a plate-shaped joint 79 formed of a paramagnetic substance therebetween. A line of magnetic force output from a rear surface (N-pole) of the fixed outer circumferential plate magnet 74 ends at the fixed outer circumferential paramagnetic body 76, and thus is not diffused to the outside.

Since the magnetron sputtering apparatus according to Embodiment 5 of the present invention can effectively prevent electrification of the wafer W during sputter film formation due to the configuration as described above, charge-up damage can be effectively avoided and yield can be improved.

While the present invention has been described with reference to the very appropriate embodiments, the present invention is not limited to the embodiments, and various modifications may be made without departing from the scope of the attached

1-16. (canceled)

17. A magnetron sputtering apparatus comprising:
a processing container which is depressurizable to evacuate gas;
a rotatable stage which supports a semiconductor wafer in the processing container;
a rotation driving unit which rotates the stage at a desired rotation speed;
a plurality of targets which are arranged to face the stage such that the plurality of targets each have a length equal to or greater than a predetermined value in a first direction and are arranged at predetermined intervals in a second direction perpendicular to the first direction;
a gas supply mechanism which supplies a sputtering gas into the processing container;
a power supply mechanism which discharges the sputtering gas in the processing container; and
a magnetic field generation mechanism which comprises a magnet provided at a rear side of each of the plurality of targets in order to confine a plasma, which is generated in the processing container, in the vicinity of each of the plurality of targets,
wherein a plurality of thin and long deposition regions are arranged such that the plurality of thin and long deposition regions each cross in the first direction a circular reference region having a diameter equal to that of the semiconductor wafer, and are arranged at predetermined intervals in the second direction,
wherein one of the plurality of thin and long deposition regions is disposed such that one side of sides thereof extending in the first direction passes through a substantial center of the circular reference region,
wherein another of the plurality of thin and long deposition regions is disposed such that one side of sides thereof extending in the first direction passes through a substantial edge of the circular reference region,
wherein a value obtained by summing widths of the plurality of thin and long deposition regions in the second direction is substantially equal to a radius of the circular reference region,
wherein the semiconductor wafer is disposed at a position overlapping with the circular reference region,
wherein the stage and the semiconductor wafer are coaxially rotated by the rotation driving unit and sputtering particles emitted from surfaces of the plurality of targets are incident on the corresponding thin and long deposition regions, to form a deposition film of the sputtering particles on a surface of the semiconductor wafer.

18. A magnetron sputtering apparatus comprising:
a processing container which is depressurizable to evacuate gas;
a rotatable stage which supports a semiconductor wafer in the processing container;
a rotation driving unit which rotates the stage at a desired rotation speed;
a plurality of targets which are arranged to face the stage such that the plurality of targets each have a length equal to or greater than a predetermined value in a first direction and are arranged at predetermined intervals in a second direction perpendicular to the first direction;
a gas supply unit which supplies a sputtering gas into the processing container;
a power supply unit which discharges the sputtering gas in the processing container; and
a magnetic field generation mechanism which comprises a magnet provided at a rear side of each of the plurality of targets in order to confine a plasma, which is generated in the processing container, in the vicinity of each of the targets,
wherein a plurality of thin and long deposition regions are arranged such that the plurality of thin and long deposition regions each cross in the first direction a circular reference region having a diameter equal to that of the semiconductor wafer and are arranged at predetermined intervals in the second direction,
wherein one of the plurality of thin and long deposition regions is disposed such that one side of sides thereof extending in the first direction passes through a substantial center of the circular reference region,
wherein another of the plurality of thin and long deposition regions is disposed such that one side of sides thereof extending in the first direction passes through a substantial edge of the circular reference region,
wherein a value obtained by summing widths of the plurality of thin and long deposition regions in the second direction is substantially equal to a radius of the circular reference region,
wherein the semiconductor wafer is disposed at a position where a center of the semiconductor wafer is spaced apart from the center of the circular reference region by a predetermined distance within a surface including the circular reference region,
wherein the semiconductor wafer is eccentrically rotated by rotating the stage by using the rotation driving unit and sputtering particles emitted from surfaces of the plurality of targets are incident on the corresponding thin and long deposition regions, to form a deposition film of the sputtering particles on a surface of the semiconductor wafer.

19. The magnetron sputtering apparatus of claim 17, wherein, when a radius of the semiconductor wafer is R and a number of the thin and long deposition regions is N (N is an integer equal to or greater than 2), a width of each of the plurality of thin and long deposition regions in the second direction is R/N.

20. A magnetron sputtering apparatus comprising:
a processing container which is depressurizable to evacuate gas;
a rotatable stage which supports a semiconductor wafer in the processing container;
a rotation driving unit which rotates the stage at a desired rotation speed;
a plurality of targets which are arranged to face the stage such that the plurality of targets each have a length equal to or greater than a predetermined value in a first direction and are arranged at predetermined intervals in a second direction perpendicular to the first direction;
a gas supply mechanism which supplies a sputtering gas into the processing container;
a power supply mechanism for discharging the sputtering gas in the processing container; and
a magnetic field generation mechanism which comprises a magnet provided at a rear side of each of the targets in order to confine a plasma, which is generated in the processing container, in the vicinity of each of the plurality of targets,
wherein a plurality of thin and long deposition regions are arranged such that the plurality of thin and long deposition regions each cross a circular reference region in the first direction, and are arranged at predetermined intervals in the second direction,
wherein, in the second direction, one of the plurality of thin and long deposition regions is disposed such that a center of the circular reference region is located in an inside of the one of the plurality of thin and long deposition regions and one side of sides thereof extending in the first direction passes through a position spaced apart from the center of the circular reference region by a first distance,
wherein another of the plurality of thin and long deposition regions is disposed such that one side of sides thereof extending in the first direction passes through a position spaced apart from an edge of the circular reference region by a second distance,
wherein, in the second direction, a value obtained by summing widths of the plurality of thin and long deposition regions is greater by a predetermined excess size than the radius of the circular reference region, and the semiconductor wafer is disposed at a position where a center of the semiconductor wafer is spaced apart from the center of the circular reference region by a third distance within a surface including the circular reference region,
wherein the semiconductor wafer is eccentrically rotated together with the stage by using the rotation driving unit and sputtering particles emitted from surfaces of the targets are incident on the corresponding thin and long deposition regions, to form a deposition film of the sputtering particles on a surface of the semiconductor wafer.

21. The magnetron sputtering apparatus of claim 20, wherein the excess size is equal to a value obtained by summing the first distance and the second distance.

22. The magnetron sputtering apparatus of claim 20, wherein the third distance is equal to the second distance.

23. The magnetron sputtering apparatus of claim 20, wherein a diameter of the semiconductor wafer is determined to be 300 mm, a number of the targets is determined to be 2, and the second distance is determined to be about 15 mm.

24. The magnetron sputtering apparatus of claim 20, wherein a diameter of the semiconductor wafer is determined to be 300 mm, a number of the targets is determined to be 3, and the second distance is determined to be about 10 mm.

25. The magnetron sputtering apparatus of claim 17, wherein at least one of the plurality of thin and long deposition regions has one pair of long sides parallel to the first direction.

26. The magnetron sputtering apparatus of claim 17, wherein at least one of the plurality of thin and long deposition regions has one pair of long sides extending in the first direction, and a recess portion or a convex portion is formed on at least one of the pair of long sides.

27. The magnetron sputtering apparatus of claim 17, wherein a length, in the first direction, of the thin and long deposition region disposed at a center side of the circular reference region from among the plurality of thin and long deposition regions is greater than a length, in the first direction, of the thin and long deposition region disposed at an edge side of the circular reference region from among the plurality of thin and long deposition regions.

28. The magnetron sputtering apparatus of claim 17, wherein the magnetic field generation mechanism forms a circular or oval plasma ring that extends from one end to another end of the surfaces of the targets in the second direction, and moves the plasma ring in the first direction.

29. The magnetron sputtering apparatus of claim 17, wherein the magnetic field generation mechanism receives the magnet disposed at the rear side of each of the plurality of targets in a common housing.

30. The magnetic sputtering device of claim 29, wherein the housing is formed of a magnetic substance.

31. The magnetic sputtering device of claim 29, wherein the housing is airtightly attached to the processing container to depressurize the housing.

32. The magnetic sputtering device of claim 17, wherein the magnetic sputtering device comprises a mechanism for varying a distance between the targets and the magnetic field generation mechanism according to a degree of erosion on the surfaces of the targets in order to constantly maintain a strength of a magnetic field on the surfaces of the plurality of targets.

33. The magnetic sputtering device of claim 17, wherein the magnetic sputtering device comprises a slit which is disposed between at least one of the plurality of targets and the stage and defines each of the plurality of thin and long deposition regions.

34. The magnetic sputtering device of claim 17, wherein the magnetron sputtering apparatus further comprises a collimator which is disposed between at least one of the plurality of targets and the stage and controls the sputtering particles emitted from the at least one target to be perpendicularly incident on the corresponding thin and long deposition region.

35. The magnetic sputtering device of claim 17, wherein the magnetron sputtering apparatus further comprises an ionization plasma generation portion which generates a plasma for ionizing the sputtering particles between at least one of the plurality of targets and the stage.

36. The magnetron sputtering apparatus of claim 17, wherein the magnetron sputtering apparatus further comprises one common backing plate which holds the plurality of targets arranged on one continuous surface.

37. The magnetron sputtering apparatus of claim 36, wherein the power supply mechanism comprises a direct current power source electrically connected commonly to the plurality of targets with the backing plate therebetween.

38. The magnetron sputtering apparatus of claim 36, wherein the power supply mechanism comprises a high frequency power source electrically connected commonly to the plurality of targets with the backing plate therebetween.

39. The magnetron sputtering apparatus of claim 17, wherein a plurality of the stages are arranged in the first direction in one processing container, and the plurality of targets are arranged to face the corresponding thin and long deposition regions while ranging over the plurality of semiconductor wafers in the first direction,
wherein sputter film formation is performed simultaneously on the semiconductor wafers by simultaneously rotating the plurality of semiconductor wafers on the plurality of stages.

40. A sputtering device comprising:
a processing container which is depressurizable to evacuate gas;
a stage which is provided in the processing container, allows a semiconductor wafer to be disposed thereon, and is rotatable about a rotary shaft; and
a sputtering mechanism which is disposed to face the stage, is able to support a target extending in a first direction, and is able to emit sputtering particles from a surface of the target to a thin and long deposition region extending in the first direction,
wherein a plurality of the sputtering mechanisms are arranged at predetermined intervals in a second direction perpendicular to the first direction,
wherein one of the plurality of sputtering mechanisms is disposed such that one side of sides extending in the first direction in the thin and long deposition region corresponding to the one of the plurality of sputtering mechanisms passes through a substantial center of the rotary shaft,
wherein another of the plurality of sputtering mechanisms is disposed such that one side of sides extending in the first direction in the thin and long deposition region corresponding to the another of the plurality of sputtering mechanisms passes through a substantial edge of a semiconductor wafer arrangement region of the stage and the other side thereof passes through the semiconductor wafer arrangement region of the stage,
wherein a value obtained by summing widths, in the second direction, of the thin and long deposition regions corresponding to the plurality of sputtering mechanisms is substantially equal to a radius of the semiconductor wafer arrangement region.

41. A sputtering device comprising:
a processing container which is depressurizable to evacuate gas;
a stage which is provided in the processing container, allows a semiconductor wafer to be disposed thereon, and is rotatable about a rotary shaft; and
a sputtering mechanism which is disposed to face the stage, is able to support a target extending in a first direction, and is able to emit sputtering particles from a surface of the target to a thin and long deposition region extending in the first direction,
wherein a plurality of the sputtering mechanisms are arranged at predetermined intervals in a second direction perpendicular to the first direction,
wherein one of the plurality of sputtering mechanisms is disposed such that one side of sides extending in the first direction in the thin and long deposition region corresponding to the one of the plurality of sputtering mechanisms passes through a substantial center of the rotary shaft,
wherein another of the plurality of sputtering mechanisms is disposed such that one side of sides extending in the first direction in the thin and long deposition region corresponding to the another of the plurality of sputtering mechanisms passes through a substantial edge of a semiconductor wafer arrangement region of the stage or a position spaced apart from the edge of the semiconductor wafer arrangement region by a predetermined distance, and the other side passes through an inside of the semiconductor wafer arrangement region of the stage,
wherein a mechanism for holding the semiconductor wafer is provided such that a center of the semiconductor wafer arrangement region is spaced apart from the center of the rotary shaft by the same distance as the predetermined distance.

42-55. (canceled)
